(19) United States
(12) Patent Application Publication
(10) Pub. No.: US 2025/0266066 A1
(43) Pub. Date: Aug. 21, 2025

(54) MEMORY DEVICES CONFIGURED TO PERFORM READ OPERATIONS FOR PSEUDO CHANNELS

(71) Applicant: SK hynix Inc., Icheon-si Gyeonggi-do (KR)

(72) Inventors: Jae Hyung PARK, Icheon-si Gyeonggi-do (KR); Jong Chan YOON, Icheon-si Gyeonggi-do (KR); Kyung Jun CHO, Icheon-si Gyeonggi-do (KR)

(73) Assignee: SK hynix Inc., Icheon-si Gyeonggi-do (KR)

(21) Appl. No.: 18/675,833

(22) Filed: May 28, 2024

(30) Foreign Application Priority Data
Feb. 15, 2024 (KR) 10-2024-0022155

(51) Int. Cl. G11C 7/10

(52) U.S. Cl. CPC G11C 7/1066; G11C 7/106; G11C 7/1069

(57) ABSTRACT

A memory device includes an alignment data strobing signal generation circuit configured to generate an alignment data strobing signal from an internal clock signal when a read operation on a specific pseudo channel of a specific rank is performed based on a read identification signal and a read channel signal, and a core pipe configured to receive the alignment data strobing signal and output core data output from the specific pseudo channel, based on the alignment data strobing signal.

### CROSS-REFERENCE TO RELATED APPLICATIONS

The present application claims priority under 35 U.S.C. 119 (a) to Korean Patent Application No. 10-2024-0022155, filed on Feb. 15, 2024, which application is incorporated herein by reference in its entirety.

### BACKGROUND

### 1. Technical Field

Various embodiments of the present disclosure generally relate to memory devices, and more particularly, to memory devices related to read operations for pseudo channels.

### 2. Related Art

Recently, stack memory systems such as a high bandwidth memory (HBM) device have been used in a wide range of applications due to excellent bandwidth and energy efficiency. Unlike the existing memory system that uses a parallel data bus, the stack memory system includes a stack memory device composed of a base die and a plurality of core dies interconnected by through silicon vias (TSV, hereinafter referred to as “through vias”). When the base die receives core data output from the core die and transmits the core data to a controller during a read operation, the stack memory device can control the core data to be transmitted from the core die to the base die using a data strobing signal generated based on an internal clock signal and to be output from the base die.

### SUMMARY

In accordance with an embodiment of the present disclosure, a memory device may include an alignment data strobing signal generation circuit configured to generate an alignment data strobing signal from an internal clock signal when a read operation on a specific pseudo channel of a specific rank is performed based on a read identification signal and a read channel signal, and a core pipe configured to receive the alignment data strobing signal and output core data output from the specific pseudo channel, based on the alignment data strobing signal.

In addition, in accordance with an embodiment of the present disclosure, a memory device may include a plurality of core dies stacked over a base die. In an embodiment, each of the plurality of core dies may include an alignment data strobing signal generation circuit configured to receive an internal clock signal, a read identification signal, and a read channel signal from the base die to generate an alignment data strobing signal. In an embodiment, the alignment data strobing signal generation circuit may generate a latch identification signal and a latch channel signal from the read identification signal and the read channel signal in-phase with the internal clock signal, generate the alignment data strobing signal, based on the latch identification signal, the latch channel signal, and a core identification signal, generate an inverted latch identification signal and an inverted latch channel signal from the read identification signal and the read channel signal out-phase with the internal clock signal, and generate the alignment data strobing signal, based on the inverted latch identification signal, the inverted latch channel signal, and the core identification signal.

In addition, in accordance with an embodiment of the present disclosure, a memory device may include a plurality of core dies stacked over a base die. In an embodiment, each of the plurality of core dies may include an alignment data strobing signal generation circuit configured to receive an internal clock signal, a read identification signal, and a read channel signal from the base die to generate an alignment data strobing signal, and a read data strobing signal transmission circuit configured to generate a read data strobing signal, based on the alignment data strobing signal, and transmit the read data strobing signal to the base die. In an embodiment, the read data strobing signal generated from each of the core dies forming the same rank among the plurality of core dies may be transmitted to the base die through the same through via arrays.

In addition, in accordance with an embodiment of the present disclosure, a memory device may include a plurality of core dies stacked over a base die, each of the plurality of core dies may include a plurality of channels, each of the plurality of channels may include a first pseudo channel and a second pseudo channel, and the plurality of channels may form a first rank and a second rank for setting bandwidth. In an embodiment, when a read operation on the first pseudo channel of the first rank is performed, the memory device may generate a first alignment data strobing signal from an internal clock signal, based on a read identification signal and a read channel signal, generate a first read data strobing signal from the first alignment data strobing signal during a first transmission period, based on the first alignment data strobing signal, and when a read operation on the first pseudo channel of the second rank is performed, the memory device may generate a second alignment data strobing signal from the internal clock signal, based on the read identification signal and the read channel signal, and generate a second read data strobing signal from the second alignment data strobing signal during a second transmission period, based on the second alignment data strobing signal.

In addition, in accordance with an embodiment of the present disclosure, a memory device may include a plurality of core dies stacked over a base die, each of the plurality of core dies may include a plurality of channels, each of the plurality of channels may include a first pseudo channel and a second pseudo channel, and the plurality of channels may form a first rank and a second rank for setting bandwidth. In an embodiment, when a read operation on the first pseudo channel of the first rank is performed, the memory device may generate a first alignment data strobing signal from an internal clock signal, based on a read identification signal and a read channel signal, generate a first read data strobing signal from the first alignment data strobing signal during a first transmission period, based on the first alignment data strobing signal, and when a read operation on the second pseudo channel of the second rank is performed, the memory device may generate a second alignment data strobing signal from the internal clock signal, based on the read identification signal and the read channel signal, and generate a second read data strobing signal from the second alignment data strobing signal during a second transmission period, based on the second alignment data strobing signal.

In addition, in accordance with an embodiment of the present disclosure, a memory device may include a plurality of core dies stacked over a base die, each of the plurality of core dies may include a plurality of channels, each of the plurality of channels may include a first pseudo channel and a second pseudo channel, and the plurality of channels may form a rank for setting bandwidth. In an embodiment, when a read operation on the first pseudo channel of the rank is performed, the memory device may generate a first alignment data strobing signal from an internal clock signal, based on a read identification signal and a read channel signal, generate a first read data strobing signal from the first alignment data strobing signal during a first transmission period, based on the first alignment data strobing signal, when a read operation on the second pseudo channel of the rank is performed, the memory device may generate a second alignment data strobing signal from the internal clock signal, based on the read identification signal and the read channel signal, and generate a second read data strobing signal from the second alignment data strobing signal during a second transmission period, based on the second alignment data strobing signal.

### BRIEF DESCRIPTION OF THE DRAWINGS

FIG. 1 illustrates a configuration of a stack memory device according to an embodiment of the present disclosure.

FIG. 2 illustrates a configuration according to an embodiment of a base die included in the stack memory device illustrated in FIG. 1.

FIG. 3 illustrates an embodiment of a read operation performed in a base die illustrated in FIG. 2.

FIG. 4 illustrates a configuration according to an embodiment of a first core die included in the stack memory device illustrated in FIG. 1.

FIG. 5 illustrates a configuration according to an embodiment of each of channels included in each of the core dies.

FIG. 6 illustrates a configuration according to an example of a peripheral region illustrated in FIG. 5.

FIG. 7 illustrates a configuration according to an embodiment of an alignment data strobing signal generation circuit included in the peripheral region illustrated in FIG. 6.

FIG. 8 illustrates a configuration according to an embodiment of a latch signal generation circuit included in the alignment data strobing signal generation circuit illustrated in FIG. 7.

FIG. 9 illustrates a configuration according to an embodiment of an internal clock signal alignment circuit included in the alignment data strobing signal generation circuit illustrated in FIG. 7.

FIG. 10 illustrates a circuit according to an embodiment of an in-phase activation signal generation circuit illustrated in FIG. 9.

FIG. 11 illustrates an example of a read identification signal that can indicate a rank on which a read operation is performed.

FIG. 12 illustrates an example of a core identification signal that can indicate the core die and rank on which a read operation is performed.

FIG. 13 illustrates an example of a latch channel signal that can indicate a pseudo channel on which a read operation is performed.

FIG. 14 illustrates a circuit according to an embodiment of an out-phase activation signal generation circuit illustrated in FIG. 9.

FIGS. 15 and 16 illustrate the operation of an embodiment of an alignment data strobing signal generation circuit.

FIG. 17 illustrates a configuration according to another example of the peripheral region illustrated in FIG. 5.

FIG. 18 illustrates a configuration according to an embodiment of a first read data strobing signal transmission circuit included in the peripheral region illustrated in FIG. 17.

FIG. 19 illustrates a circuit according to an embodiment of a transmission activation signal generation circuit included in the first read data strobing signal transmission circuit illustrated in FIG. 18.

FIG. 20 illustrates a configuration of an embodiment of a read data strobing signal generation circuit included in the first read data strobing signal transmission circuit illustrated in FIG. 18.

FIG. 21 illustrates an embodiment of a read operation performed in the peripheral region illustrated in FIG. 17.

FIG. 22 illustrates a configuration of a stack memory device according to another embodiment of the present disclosure.

### DETAILED DESCRIPTION

In the following description of embodiments, when a parameter is referred to as being “predetermined,” it may be intended to mean that a value of the parameter is determined in advance when the parameter is used in a process or an algorithm. The value of the parameter may be set when the process or the algorithm starts or may be set during a period in which the process or the algorithm is executed.

It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A logic “high” level and a logic “low” level may be used to describe logic levels of electric signals. A signal having a logic “high” level may be distinguished from a signal having a logic “low” level. For example, when a signal having a first voltage corresponds to a signal having a logic “high” level, a signal having a second voltage corresponds to a signal having a logic “low” level. In an embodiment, the logic “high” level may be set as a voltage level which is higher than a voltage level of the logic “low” level. Meanwhile, logic levels of signals may be set to be different or opposite according to the embodiments. For example, a certain signal having a logic “high” level in one embodiment may be set to have a logic “low” level in another embodiment.

The term “logic bit set” may mean a combination of logic levels of bits included in a signal. When the logic level of each of the bits included in the signal is changed, the logic bit set of the signal may be set differently. For example, when the signal includes two bits, when the logic level of each of the two bits included in the signal is “logic low level, logic low level”, the logic bit set of the signal may be set as the first logic bit set, and when the logic level of each of the two bits included in the signal is “a logic low level and a logic high level”, the logic bit set of the signal may be set as the second logic bit set.

Various embodiments of the present disclosure will be described hereinafter in more detail with reference to the accompanying drawings. However, the embodiments described herein are for illustrative purposes only and are not intended to limit the scope of the present disclosure.

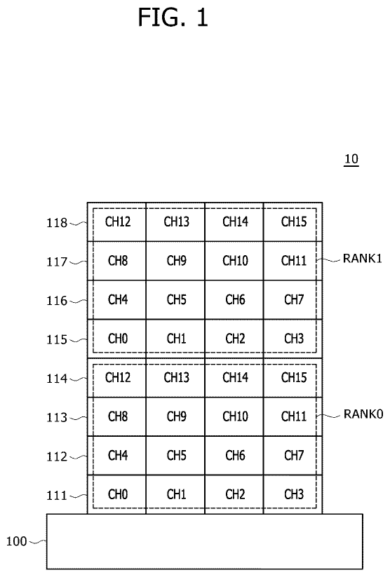

FIG. 1 illustrates a configuration of a stack memory device 10 according to an embodiment of the present disclosure. As illustrated in FIG. 1, the stack memory device 10 may include a base die 100 and a plurality of core dies 111, 112, 113, 114, 115, 116, 117, and 118.

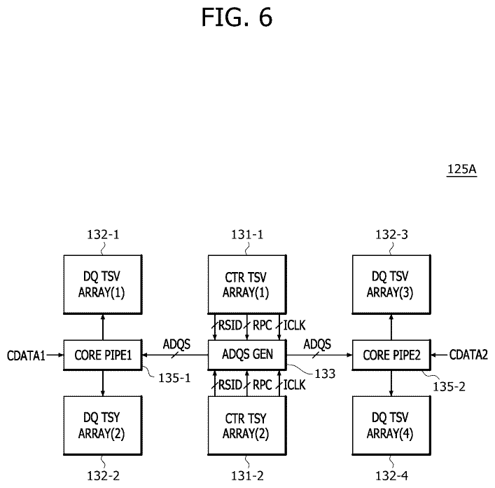

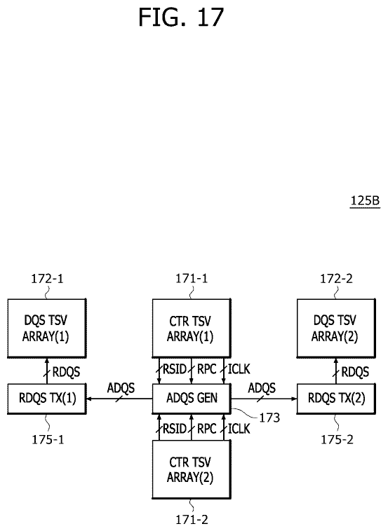

The base die 100 may control the internal operations of each of the core dies 111, 112, 113, 114, 115, 116, 117, and 118, for example, a write operation of storing data, a read operation of outputting data, and the like according to the control of a memory controller (not illustrated). The base die 100 may control each of the core dies 111, 112, 113, 114, 115, 116, 117, and 118 such that data is stored in each of the core dies 111, 112, 113, 114, 115, 116, 117, and 118 when the write operation on each of the core dies 111, 112, 113, 114, 115, 116, 117, and 118 is performed according to the control of the memory controller (not illustrated). When the read operation on each of the core dies 111, 112, 113, 114, 115, 116, 117, and 118 is performed, the base die 100 may receive core data (e.g., CDATA1 and CDATA2 in FIG. 6) output from each of the core dies 111, 112, 113, 114, 115, 116, 117, and 118 to transmit the core data to the memory controller (not illustrated) in synchronization with a read data strobing signal (e.g., RDQS in FIG. 17).

Each of the plurality of core dies 111, 112, 113, 114, 115, 116, 117, and 118 may be stacked over the base die 100. For example, the core die 111 may be stacked over the base die 100, the core die 112 may be stacked over the core die 111, the core die 113 may be stacked over the core die 112, the core die 114 may be stacked over the core die 113, the core die 115 may be stacked over the core die 114, the core die 116 may be stacked over the core die 115, the core die 117 may be stacked over the core die 116, and the core die 118 may be stacked over the core die 117.

Each of the plurality of core dies 111, 112, 113, 114, 115, 116, 117, and 118 may include a plurality of channels. The core die 111 may include first to fourth channels CH0˜CH3. As used herein, the tilde “˜” indicates a range of components. For example, “CH0˜CH3” indicates the channels CH0, CH1, CH2, and CH3 shown in FIG. 1. The core die 112 may include fifth to eighth channels CH4˜CH7. The core die 113 may include ninth to twelfth channels CH8˜CH11. The core die 114 may include thirteenth to sixteenth channels CH12˜CH15. The core die 115 may include first to fourth channels CH0˜CH3. The core die 116 may include fifth to eighth channels CH4˜CH7. The core die 117 may include ninth to twelfth channels CH8˜CH11. The core die 118 may include thirteenth to sixteenth channels CH12˜CH15. The first channel CH0 of the core die 111 and the first channel CH0 of the core die 115 may share at least one data path through which data is input and output. The second channel CH1 of the core die 111 and the second channel CH1 of the core die 115 may share at least one data path through which data is input and output. The third channel CH2 of the core die 111 and the third channel CH2 of the core die 115 may share at least one data path through which data is input and output. The fourth channel CH3 of the core die 111 and the fourth channel CH3 of the core die 115 may share at least one data path through which data is input and output. The fifth channel CH4 of the core die 112 and the fifth channel CH4 of the core die 116 may share at least one data path through which data is input and output. The sixth channel CH5 of the core die 112 and the sixth channel CH5 of the core die 116 may share at least one data path through which data is input and output. The seventh channel CH6 of the core die 112 and the seventh channel CH6 of the core die 116 may share at least one data path through which data is input and output. The eighth channel CH7 of the core die 112 and the eighth channel CH7 of the core die 116 may share at least one data path through which data is input and output. The ninth channel CH8 of the core die 113 and the ninth channel CH8 of the core die 117 may share at least one data path through which data is input and output. The tenth channel CH9 of the core die 113 and the tenth channel CH9 of the core die 117 may share at least one data path through which data is input and output. The eleventh channel CH10 of the core die 113 and the eleventh channel CH10 of the core die 117 may share at least one data path through which data is input and output. The twelfth channel CH11 of the core die 113 and the twelfth channel CH11 of the core die 117 may share at least one data path through which data is input and output. The thirteenth channel CH12 of the core die 114 and the thirteenth channel CH12 of the core die 118 may share at least one data path through which data is input and output. The fourteenth channel CH13 of the core die 114 and the fourteenth channel CH13 of the core die 118 may share at least one data path through which data is input and output. The fifteenth channel CH14 of the core die 114 and the fifteenth channel CH14 of the core die 118 may share at least one data path through which data is input and output. The sixteenth channel CH15 of the core die 114 and the sixteenth channel CH15 of the core die 118 may share at least one data path through which data is input and output. The first to fourth channels CH0˜CH3 of the core die 111, the fifth to eighth channels CH4˜CH7 of the core die 112, the ninth to twelfth channels CH8˜CH11 of the core die 113, and the thirteenth to sixteenth channels CH12˜CH15 of the core die 114 may form a first rank RANK0 for setting a band width. The first to fourth channels CH0˜CH3 of the core die 115, the fifth to eighth channels CH4˜CH7 of the core die 116, the ninth to twelfth channels CH8˜CH11 of the core die 117, and the thirteenth to sixteenth channels CH12˜CH15 of the core die 118 may form a second rank RANK1 for setting a band width.

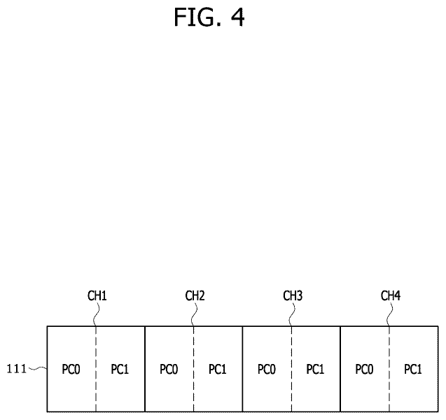

Each of the first to fourth channels CH0˜CH3 of the core die 111, each of the fifth to eighth channels CH4˜CH7 of the core die 112, each of the ninth to twelfth channels CH8˜CH11 of the core die 113, each of the thirteenth to sixteenth channels CH12˜CH15 of the core die 114, each of the first to fourth channels CH0˜CH3 of the core die 115, each of the fifth to eighth channels CH4˜CH7 of the core die 116, each of the ninth to twelfth channels CH8˜CH11 of the core die 117, and each of the thirteenth to sixteenth channels CH12˜CH15 of the core die 118 may include a plurality of pseudo channels (e.g., PC0 and PC1 in FIG. 4) that operate independently to increase the bandwidth. The internal operations, such as write operations and read operations, for each of the plurality of pseudo channels (e.g., PC0 and PC1 in FIG. 4) included in the first to sixteenth channels CH0˜CH15 may be performed independently.

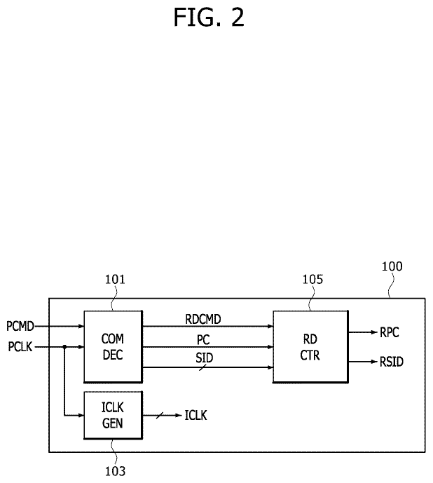

FIG. 2 illustrates a configuration of an embodiment of the base die 100 illustrated in FIG. 1. As illustrated in FIG. 2, the base die 100 may include a command decoder (COM DEC) 101, an internal clock signal generation circuit (ICLK GEN) 103, and a read control circuit (RD CTR) 105.

The command decoder 101 may generate a read command RDCMD, a channel signal PC, and an identification signal SID, based on an external clock signal PCLK and an external command PCMD received from a memory controller (not illustrated). The command decoder 101 may decode the external command PCMD in synchronization with the external clock signal PCLK to generate the read command RDCMD, the channel signal PC, and the identification signal SID. The external command PCMD may indicate a read operation for a specific pseudo channel (e.g., PC0 or PC1 in FIG. 4) included in a specific rank (e.g., RANK0 or RANK1). As an example, the command decoder 101 may generate the read command RDCMD set to a binary bit of ‘1’, the channel signal PC set to a binary bit of ‘0’, and the identification signal SID set to a binary bit set of ‘00’ to instruct a read operation for the first pseudo channel PC0 of the first rank RANK0. As another example, the command decoder 101 may generate the read command RDCMD set to a binary bit of ‘1’, the channel signal PC set to a binary bit of ‘1’, and the identification signal SID set to a binary bit set of ‘01’ to indicate a read operation for the second pseudo channel PC1 of the second rank RANK1.

The internal clock signal generation circuit 103 may generate an internal clock signal ICLK, based on the external clock signal PCLK. The internal clock signal generation circuit 103 may divide the external clock signal PCLK to generate the internal clock signal ICLK. The internal clock signal ICLK may be set in multiple numbers. As an example, the internal clock signal generation circuit 103 may divide the external clock signal PCLK by 2 to generate a first internal clock signal CLK1, a second internal clock signal CLK2, a first inverted internal clock signal CLK1B, and a second inverted internal clock signal CLK2B that are set to have a cycle twice as large as that of the external clock signal PCLK. In this case, the second internal clock signal CLK2 may be generated later than the first internal clock signal CLK1 by a half cycle of the external clock signal PCLK, the first inverted internal clock signal CLK1B may be generated later than the second internal clock signal CLK2 by a half cycle of the external clock signal PCLK, and the second inverted internal clock signal CLK2B may be generated later than the first inverted internal clock signal CLK1B by a half cycle of the external clock signal PCLK. Accordingly, the first inverted internal clock signal CLK1B may be generated to have an inverted phase with the first internal clock signal CLK1, and the second inverted internal clock signal CLK2B may be generated to have an inverted phase with the second internal clock signal CLK2.

The read control circuit 105 may be electrically connected to the command decoder 101 to receive the read command RCMD, the channel signal PC, and the identification signal SID from the command decoder 101. The read control circuit 105 may generate a read channel signal RPC and a read identification signal RSID when a read operation for a specific pseudo channel (e.g., PC0 or PC1 in FIG. 4) of the specific rank (e.g., RANK0 or RANK1 in FIG. 4) is performed, based on the read command RDCMD, the channel signal PC, and the identification signal SID. As an example, when the read operation is performed for the first pseudo channel PC0 of the first rank RANK0, the read control circuit 105 may generate the read channel signal RPC set to a binary bit set of ‘01’ and the read identification signal RSID set to a binary set of ‘00’. As another example, when the read operation is performed for the second pseudo channel PC1 of the second rank RANK1, the read control circuit 105 may generate the read channel signal RPC set to a binary bit set of ‘10’ and the read identification signal RSID set to a binary set of ‘01’.

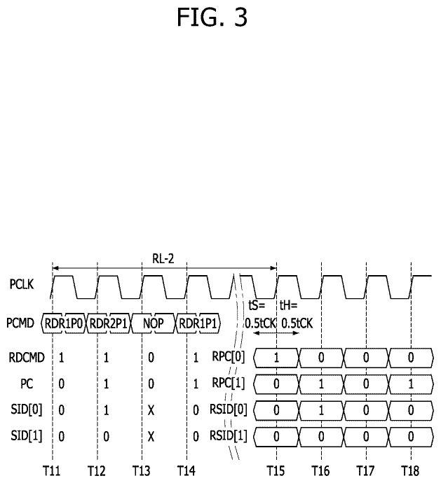

FIG. 3 illustrates an embodiment of the read operation performed in the base die 100A illustrated in FIG. 2.

As illustrated in FIG. 3, at the time point of T11, when a read operation RDR1P0 on the first pseudo channel PC0 of the first rank RANK0 is performed, the command decoder 101 may decode the external command PCMD in synchronization with the external clock signal PCLK to generate the read command RDCMD set to a binary bit of ‘1’, the channel signal PC set to a binary bit of ‘0’, and the identification signal SID set to a binary bit set of ‘00’. At the time point of T15, when a read control period RL-2 has elapsed from the time point of T11, the read control circuit 105 may generate the read channel signal RPC and the read identification signal RSID, based on the read command RDCMD, the channel signal PC, and the identification signal SID. That is, when the read operation on the first pseudo channel PC0 of the first rank RANK0 is performed, the read control circuit 105 may receive the read command RDCMD set to a binary bit of ‘1’, the channel signal PC set to a binary bit of ‘0’, and the identification signal SID set to a binary bit set of ‘00’ to generate the read channel signal RPC set to a binary bit set of ‘01’ and the read identification signal RSID set to a binary bit set of ‘00’. The read control period RL-2 may be set as a period obtained by subtracting 2 cycles of the external clock signal PCLK from the read latency, but this is only an example and the present disclosure is not limited thereto.

As illustrated in FIG. 3, when a read operation RDR2P1 is performed on the second pseudo channel PC1 of the second rank RANK1 at the time point of T12, the command decoder 101 may decode the external command PCMD in synchronization with the external clock signal PCLK to generate the read command RCMD set to a binary bit of ‘1’, the channel signal PC set to a binary bit of ‘1’, and the identification signal SID set to a binary bit set of ‘01’ (i.e., SID [0] having a binary bit of ‘1’ and SID [1] having a binary bit of ‘0’). At the time point of T16, when the read control period RL-2 has elapsed from the time point of T12, the read control circuit 105 may generate the read channel signal RPC and the read identification signal RSID, based on the read command RDCMD, the channel signal PC, and the identification signal SID. That is, when the read operation on the second pseudo channel PC1 of the second rank RANK1 is performed, the read control circuit 105 may receive the read command RCMD set to a binary bit of ‘1’, the channel signal PC set to a binary bit of ‘1’, and the identification signal SID set to a binary bit set of ‘01’ to generate the read channel signal RPC set to a binary bit set of ‘10’ (i.e., RPC [0] having a binary bit of ‘0’ and RPC [1] having a binary bit of ‘1’) and the read identification signal RSID set to a binary bit set of ‘01’ (i.e., RSID [0] having a binary bit of ‘1’ and RSID [1] having a binary bit of ‘0’).

As illustrated in FIG. 3, when no operation NOP is performed at the time point of T13, the command decoder 101 may decode the external command PCMD in synchronization with the external clock signal PCLK to generate the read command RDCMD set to a binary bit of ‘0’ and the channel signal PC set to a binary bit of ‘0’. At the time point of T17, when the read control period RL-2 has elapsed from the time point of T13, the read control circuit 105 may generate the read channel signal RPC and the read identification signal RSID, based on the read command RDCMD and the channel signal PC. That is, when no operation NOP is performed, the read control circuit 105 may receive the read command RCMD set to a binary bit of ‘0’ and the channel signal PC set to a binary bit of ‘0’ to generate the read channel signal RPC set to a binary bit set of ‘00’ and the read identification signal RSID set to a binary bit set of ‘00’.

As illustrated in FIG. 3, when a read operation RDR1P1 is performed on the second pseudo channel PC1 of the first rank RANK0 at the time point of T14, the command decoder 101 may decode the external command PCMD in synchronization with the external clock signal PCLK to generate the read command RDCMD set to a binary bit of ‘1’, the channel signal PC set to a binary bit of ‘1’, and the identification signal SID set to a binary bit set of ‘00’. At the time point of T18, when the read control period RL-2 has elapsed from the time point of T14, the read control circuit 105 may generate the read channel signal RPC and the read identification signal RSID, based on the read command RDCMD, the channel signal PC, and the identification signal SID. That is, when the read operation RDR1P2 on the second pseudo channel PC1 of the first rank RANK0 is performed, the read control circuit 105 may receive the read command RCMD set to a binary bit of ‘1’, the channel signal PC set to a binary bit of ‘1’, and the identification signal SID set to a binary bit set of ‘00’ to generate the read channel signal RPC set to a binary bit set of ‘10’ and the read identification signal RSID set to a binary bit set of ‘00’.

FIG. 4 illustrates a configuration of an example of the core die 111 included in the stack memory device illustrated in FIG. 1. As illustrated in FIG. 4, the first core die 111 may include first to fourth channels CH0˜CH3. Each of the first to fourth channels CH0˜CH3 may include a first pseudo channel PC0 and a second pseudo channel PC1 that operate independently to increase the bandwidth. The internal operations for each of the first pseudo channel PC0 and the second pseudo channel PC1, for example, read operations, write operations, and the like may be performed independently.

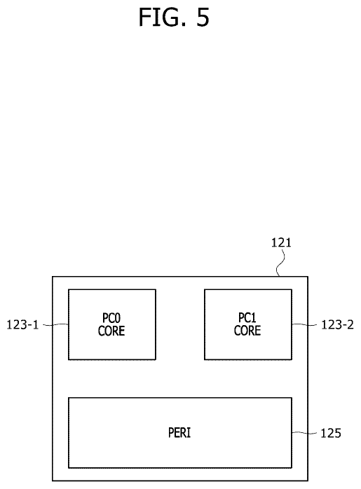

FIG. 5 illustrates a configuration of a channel 121 according to an example of each of the first to sixteenth channels CH0˜CH15 included in each of the core dies 111, 112, 113, 114, 115, 116, 117, and 118.

As illustrated in FIG. 5, the channel 121 may include a first pseudo core region (PC0 CORE) 123-1, a second pseudo core region (PC1 CORE) 123-2, and a peripheral region (PERI) 125.

The first pseudo core region 123-1 may include a memory cell array in which data input when a write operation for the first pseudo channel PC0 is performed is stored. The first pseudo core region 123-1 may include the memory cell array from which data is output when a read operation for the first pseudo channel PC0 is performed.

The second pseudo core region 123-2 may include a memory cell array in which data input when a write operation for the second pseudo channel PC1 is performed is stored. The second pseudo core region 123-2 may include the memory cell array from which data is output when a read operation for the second pseudo channel PC1 is performed.

The peripheral region 125 may include logic circuits that control the write operation for the first pseudo channel PC0 or the second pseudo core region 123-2. The peripheral region 125 may include logic circuits that control the read operation for the first pseudo channel PC0 or the second pseudo core region 123-2.

FIG. 6 illustrates a configuration of a peripheral region 125A according to an example of the peripheral region 125 illustrated in FIG. 5.

As illustrated in FIG. 6, the peripheral region 125A may include control through via arrays (CTR TSV ARRAY (1)˜CTR TSV ARRAY (2)) 131-1˜131-2, data through via arrays (DQ TSV ARRAY (1)˜DQ TSV ARRAY (4)) 132-1˜132-4, an alignment data strobing signal generation circuit (ADQS GEN) 133, a first core pipe (CORE PIPE1) 135-1, and a second core pipe (CORE PIPE2) 135-2.

Each of the control through via arrays 131-1 and 131-2 may transmit the read identification signal RSID, the read channel signal RPC, and the internal clock signal ICLK that are generated in the base die (100 in FIG. 1) to each of the plurality of core dies 111, 112, 113, 114, 115, 116, 117, and 118, passing through the base die 100 and the plurality of core dies 111, 112, 113, 114, 115, 116, 117, and 118. The control through via array 131-1 may be located at the top center of the peripheral region 125A, and the control through via array 131-2 may be located at the bottom center of the peripheral region 125A, but this is only an example and the present disclosure is not limited thereto.

Each of the data through via arrays 132-1, 132-2, 132-3, and 132-4 may transmit the first core data CDATA1 and the second core data CDATA2 output from each of the plurality of core dies 111, 112, 113, 114, 115, 116, 117, and 118, passing through the plurality of core dies 111, 112, 113, 114, 115, 116, 117, and 118 to the base die 100. The data through via array 132-1 may be located in the upper left portion of the peripheral region 125A, the data through via array 132-2 may be located in the lower left portion of the peripheral region 125A, the data through via array 132-3 may be located in the upper right portion of the peripheral region 125A, and the data through via array 132-4 may be located in the lower right portion of the peripheral region 125A, but this is only an example and the present disclosure is not limited thereto.

The alignment data strobing signal generation circuit 133 may be connected to the control through via arrays 131-1 and 131-2 to receive the read identification signal RSID, the read channel signal RPC, and the internal clock signal ICLK from the control through via arrays 131-1 and 131-2. The alignment data strobing signal generation circuit 133 may generate the alignment data strobing signal ADQS, based on the read identification signal RSID, the read channel signal RPC, and the internal clock signal ICLK. The alignment data strobing signal generation circuit 133 may latch the read identification signal RSID and the read channel signal RPC in synchronization with the internal clock signal ICLK, and may generate the alignment data strobing signal ADQS to output the first core data CDATA1 or the second core data CDATA2 when the read operation for the specific pseudo channel (e.g., PC0 or PC1) of the specific rank (e.g., RANK0 or RANK1) is performed based on the latched read identification signal RSID and read channel signal RPC. The first core data CDATA1 may be output from the first pseudo core region 123-1 when the read operation is performed on the first pseudo channel PC0 of the specific rank (e.g., RANK0 or RANK1). The second core data CDATA2 may be output from the second pseudo core region 123-2 when the read operation is performed on the second pseudo channel PC1 of the specific rank (e.g., RANK0 or RANK1).

The first core pipe 135-1 may be electrically connected to the alignment data strobing signal generation circuit 133 to receive the alignment data strobing signal ADQS from the alignment data strobing signal generation circuit 133. The first core pipe 135-1 may output the first core data CDATA1 to the base die 100 through the data through via arrays 132-1 and 132-2, based on the alignment data strobing signal ADQS. For example, the first core pipe 135-1 may output the first core data CDATA1 to the base die 100 through the data through via arrays 132-1 and 132-2 when the read operation is performed on the first pseudo channel PC0 of the specific rank (e.g., RANK0 or RANK1).

The second core pipe 135-2 may be electrically connected to the alignment data strobing signal generation circuit 133 to receive the alignment data strobing signal ADQS from the alignment data strobing signal generation circuit 133. The second core pipe 135-2 may output the second core data CDATA2 to the base die 100 through the data through via arrays 132-1 and 132-2, based on the alignment data strobing signal ADQS. For example, the second core pipe 135-2 may output the second core data CDATA2 to the base die 100 through the data through via arrays 132-1 and 132-2 when the read operation is performed on the second pseudo channel PC1 of the specific rank (e.g., RANK0 or RANK1).

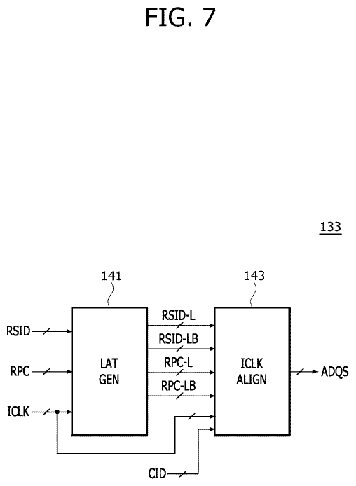

FIG. 7 illustrates a configuration of an embodiment of the alignment data strobing signal generation circuit 133 illustrated in FIG. 6.

As illustrated in FIG. 7, the alignment data strobing signal generation circuit 133 may include a latch signal generation circuit (LAT GEN) 141 and an internal clock signal alignment circuit (ICLK ALIGN) 143.

The latch signal generation circuit 141 may generate a latch identification signal RSID-L, an inverted latch identification signal RSID-LB, a latch channel signal RPC-L, and an inverted latch channel signal RPC-LB, based on the internal clock signal ICLK, the read identification signal RSID, and the read channel signal RPC. The latch signal generation circuit 141 may latch the read identification signal RSID and the read channel signal RPC in synchronization with the internal clock signal ICLK to generate the latch identification signal RSID-L, the inverted latch identification signal RSID-LB, the latch channel signal RPC-L, and the inverted latch channel signal RPC-LB. For example, the latch signal generation circuit 141 may latch the read identification signal RSID and the read channel signal RPC in-phase with the internal clock signal ICLK to generate the latch identification signal RSID-L and the latch channel signal RPC-L. When the internal clock signal ICLK includes a first internal clock signal ICLK1, a second internal clock signal ICLK2, a first inverted internal clock signal ICLK1B, and a second inverted internal clock signal ICLK2B, in-phase with the internal clock signal ICLK may be set to synchronizing with the first internal clock signal ICLK1. However, this is only an example and the present disclosure is not limited thereto.

Meanwhile, the latch signal generation circuit 141 may latch the read identification signal RSID and the read channel signal RPC out-phase with the internal clock signal ICLK to generate the inverted latch identification signal RSID-LB and the inverted latch channel signal RPC-LB. Synchronizing out-phase with the internal clock signal ICLK may be set to synchronizing with the first inverted internal clock signal ICLK1B, but this is only an example and the present disclosure is not limited thereto.

The internal clock signal alignment circuit 143 may be electrically connected to the latch signal generation circuit 141 to receive the latch identification signal RSID-L, the inverted latch identification signal RSID-LB, the latch channel signal RPC-L, and the inverted latch channel signal RPC-LB from the latch signal generation circuit 141. The internal clock signal alignment circuit 143 may generate the alignment data strobing signal ADQS, based on the latch identification signal RSID-L, the inverted latch identification signal RSID-LB, the latch channel signal RPC-L, the inverted latch channel signal RPC-LB, the internal clock signal ICLK, and the core identification signal CID. The internal clock signal alignment circuit 143 may generate the alignment data strobing signal ADQS, based on the latch identification signal RSID-L, the inverted latch identification signal RSID-LB, the latch channel signal RPC-L, the inverted latch channel signal RPC-LB, and the core identification signal CID in synchronization with the internal clock signal ICLK when the read operation on the specific pseudo channel (e.g., PC0 or PC1) included in the specific rank (e.g., RANK0 or RANK1) is performed. For example, the internal clock signal alignment circuit 143 may generate the alignment data strobing signal ADQS, based on the latch identification signal RSID-L, the latch channel signal RPC-L, and the core identification signal CID in synchronization with the in-phase of the internal clock signal ICLK when the read operation on the specific pseudo channel (e.g., PC0 or PC1) included in the specific rank (e.g., RANK0 or RANK1) is performed. In addition, the internal clock signal alignment circuit 143 may generate the alignment data strobing signal ADQS, based on the inverted latch identification signal RSID-LB, the inverted latch channel signal RPC-LB, and the core identification signal CID in synchronization with the out-phase of the internal clock signal ICLK when the read operation on the specific pseudo channel (e.g., PC0 or PC1) included in the specific rank (e.g., RANK0 or RANK1) is performed. In an embodiment, the read identification signal RSID indicates the specific rank (e.g., RANK0 or RANK1) a read operation is performed on. In an embodiment, the read channel signal RPC indicates the specific pseudo channel (e.g., PC0 or PC1) a read operation is performed with.

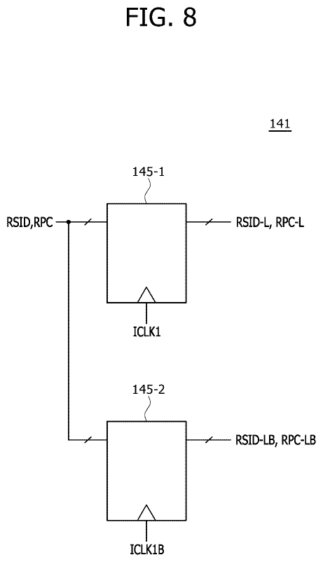

FIG. 8 illustrates a configuration of an embodiment of the latch signal generation circuit 141 illustrated in FIG. 7. As illustrated in FIG. 8, the latch signal generation circuit 141 may include a first latch 145-1 and a second latch 145-2.

The first latch 145-1 may latch the read identification signal RSID in synchronization with the first internal clock signal ICLK1 to generate the latch identification signal RSID-L. The first latch 145-1 may latch the read channel signal RPC in synchronization with the first internal clock signal ICLK1 to generate the latch channel signal RPC-L.

The second latch 145-2 may latch the read identification signal RSID in synchronization with the first inverted internal clock signal ICLK1B to generate the inverted latch identification signal RSID-LB. The second latch 145-2 may latch the read channel signal RPC in synchronization with the first inverted internal clock signal ICLK1B to generate the inverted latch channel signal RPC-LB.

The latch signal generation circuit 141A may latch the read identification signal RSID and the read channel signal RPC in synchronization with the in-phase of the internal clock signal ICLK, that is, the first internal clock signal ICLK1 to generate the latch identification signal RSID-L and the latch channel signal RPC-L. The latch signal generation circuit 141A may latch the read identification signal RSID and the read channel signal RPC in synchronization with the out-phase of the internal clock signal ICLK, that is, the first inverted internal clock signal ICLK1B to generate the inverted latch identification signal RSID-LB and the inverted latch channel signal RPC-LB.

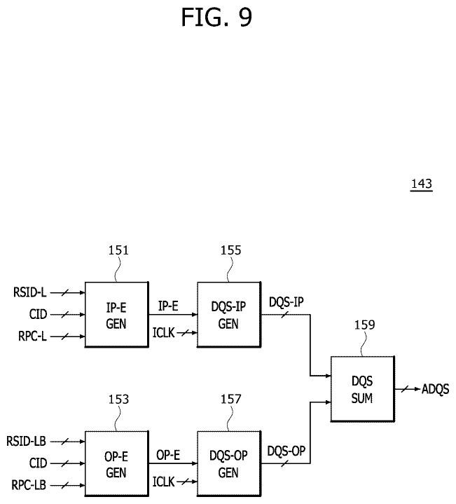

FIG. 9 illustrates a configuration of an embodiment of the internal clock signal alignment circuit 143 illustrated in FIG. 7. As illustrated in FIG. 9, the internal clock signal alignment circuit 143 may include an in-phase activation signal generation circuit (IP-E GEN) 151, an out-phase activation signal generation circuit (OP-E GEN) 153, an in-phase data strobing signal generation circuit (DQS-IP GEN) 155, an out-phase data strobing signal generation circuit (DQS-OP GEN) 157, and a data strobing signal summation circuit (DQS SUM) 159.

The in-phase activation signal generation circuit 151 may generate an in-phase activation signal IP-E, based on the latch identification signal RSID-L, the latch channel signal RPC-L, and the core identification signal CID. The in-phase activation signal generation circuit 151 may generate the in-phase activation signal IP-E that is activated when the latch identification signal RSID-L and the core identification signal CID are correspond to each other and the latch channel signal RPC-L is activated. The core identification signal CID may include information on the core die where the internal clock signal alignment circuit 143 is located and information on the rank in which the core die is included. The in-phase activation signal generation circuit 151 may generate the in-phase activation signal IP-E that is activated when the rank on which the read operation indicated by the latch identification signal RSID-L is performed corresponds to the rank including the core die indicated by the core identification signal CID and the latch channel signal RPC-L corresponding to the pseudo channel (e.g., PC0 or PC1) on which the read operation is performed is activated.

The out-phase activation signal generation circuit 153 may generate an out-phase activation signal OP-E, based on the inverted latch identification signal RSID-LB, the inverted latch channel signal RPC-LB, and the core identification signal CID. The out-phase activation signal generation circuit 153 may generate the out-phase activation signal OP-E that is activated when the inverted latch identification signal RSID-LB and the core identification signal CID are correspond to each other and the inverted latch channel signal RPC-LB is activated. The out-phase activation signal generation circuit 153 may generate the out-phase activation signal OP-E that is activated when the rank on which the read operation indicated by the inverted latch identification signal RSID-LB is performed corresponds to the rank including the core die indicated by the core identification signal CID and the inverted latch channel signal RPC-LB corresponding to the pseudo channel (e.g., PC0 or PC1) on which the read operation is performed is activated.

The in-phase data strobing signal generation circuit 155 may be electrically connected to the in-phase activation signa generation circuit 151 to receive the in-phase activation signal IP-E from the in-phase activation signal generation circuit 151. The in-phase data strobing signal generation circuit 155 may generate the in-phase data strobing signal DQS-IP from the internal clock signal ICLK, based on the in-phase activation signal IP-E. The in-phase data strobing signal generation circuit 155 may generate the in-phase data strobing signal DQS-IP from the internal clock signal ICLK when the read operation for the corresponding pseudo channel included in the core die of the corresponding rank is performed in synchronization with the in-phase of the internal clock signal ICLK and the in-phase activation signal IP-E is activated.

The out-phase data strobing signal generation circuit 157 may be electrically connected to the out-phase activation signa generation circuit 153 to receive the out-phase activation signal OP-E from the out-phase activation signal generation circuit 153. The out-phase data strobing signal generation circuit 157 may generate the out-phase data strobing signal DQS-OP from the internal clock signal ICLK, based on the out-phase activation signal OP-E. The out-phase data strobing signal generation circuit 157 may generate the out-phase data strobing signal DQS-OP from the internal clock signal ICLK when the read operation for the corresponding pseudo channel included in the core die of the corresponding rank is performed in synchronization with the out-phase of the internal clock signal ICLK and the out-phase activation signal OP-E is activated.

The data strobing signal summation circuit 159 may be electrically connected to the in-phase data strobing signal generation circuit 155 and the out-phase data strobing signal generation circuit 157 to receive the in-phase data strobing signal DQS-IP from the in-phase data strobing signal generation circuit 155 or receive the out-phase data strobing signal DQS-OP from the out-phase data strobing signal generation circuit 157. The data strobing signal summation circuit 159 may sum the in-phase data strobing signal DQS-IP and the out-phase data strobing signal DQS-OP to generate the alignment data strobing signal ADQS. For example, the data strobing signal summation circuit 159 may generate the in-phase data strobing signal DQS-IP generated in synchronization with the internal clock signal ICLK as the alignment data strobing signal ADQS when the read operation for the corresponding pseudo channel included in the core die of the corresponding rank is performed in synchronization with the in-phase of the internal clock signal ICLK. Meanwhile, the data strobing signal summation circuit 159 may generate the out-phase data strobing signal DQS-OP generated in synchronization with the internal clock signal ICLK as the alignment data strobing signal ADQS when the read operation for the corresponding pseudo channel included in the core die of the corresponding rank is performed in synchronization with the out-phase of the internal clock signal ICLK.

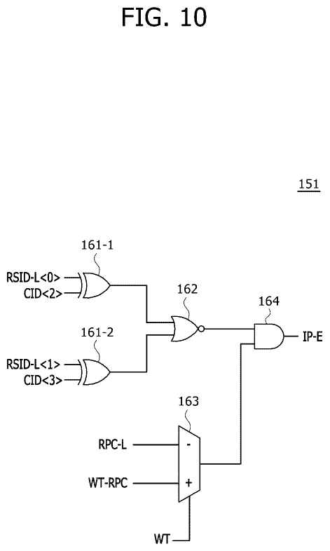

FIG. 10 illustrates a circuit of an embodiment of the in-phase activation signal generation circuit 151 illustrated in FIG. 9. As illustrated in FIG. 10, the in-phase activation signal generation circuit 151 may include exclusive OR devices 161-1 and 161-2, a NOR device 162, a selector 163, and an AND device 164.

The exclusive OR device 161-1 may receive a first bit RSID-L<0> of the latch identification signal RSID-L and a third bit CID<2> of the core identification signal CID to perform an exclusive OR operation. The exclusive OR device 161-1 may output a signal of a logic “low” level when the first bit RSID-L<0> of the latch identification signal RSID-L and the third bit CID<2> of the core identification signal CID are the same as each other, and may output a signal of a logic “high” level when the first bit RSID-L<0> of the latch identification signal RSID-L and the third bit CID<2> of the core identification signal CID are different from each other.

The exclusive OR device 161-2 may receive a second bit RSID-L<1> of the latch identification signal RSID-L and a fourth bit CID<3> of the core identification signal CID to perform an exclusive OR operation. The exclusive OR device 161-2 may output a signal of a logic “low” level when the second bit RSID-L<1> of the latch identification signal RSID-L and the fourth bit CID<3> of the core identification signal CID are the same as each other, and may output a signal of a logic “high” level when the second bit RSID-L<1> of the latch identification signal RSID-L and the fourth bit CID<3> of the core identification signal CID are different from each other.

The NOR device 162 may be electrically connected to the exclusive OR device 161-1 and the exclusive OR device 161-2 to receive the output signal of the exclusive OR device 161-1 and the output signal of the exclusive OR device 161-2 and perform a NOR operation. The NOR device 162 may output a signal of a logic “high” level when the second and first bits RSID-L<1:0> of the latch identification signal RSID-L and the fourth and third bits CID<3:2> of the core identification signal CID are the same as each other, and may output a signal of a logic “low” level when the second and first bits RSID-L<1:0> of the latch identification signal RSID-L and the fourth and third bits CID<3:2> of the core identification signal CID are different from each other. Here, the second and first bits RSID-L<1:0> of the latch identification signal RSID-L may indicate information on the rank on which the read operation is performed, and the fourth and third bits CID<3:2> of the core identification signal CID may indicate information on the rank to which the core die including the in-phase activation signal generation circuit 151 belongs. However, the number and type of the bits may be changed in various ways depending on the embodiment.

The selector 163 may selectively output one of the latch channel signal RPC-L and a write setting signal WT-RPC, based on a write signal WT. The logic level of the write signal WT may be set depending on whether a write operation is performed. For example, the write signal WT may be set to have a logic “high” level when the write operation is performed, and may be set to have a logic “low” level when the read operation is performed. The selector 163 may output the write setting signal WT-RPC when the write operation is performed, and may output the latch channel signal RPC-L when the read operation is performed. The logic level of the write signal WT and the signal selected by the selector 163 according to the write signal WT may be set in various ways depending on the embodiment.

The AND device 164 may be electrically connected to the NOR device 162 and the selector 163 to receive the output signal of the NOR device 162 and the output signal of the selector 163. The AND device 164 may receive the output signal of the NOR device 162 and the output signal of the selector 163 to perform an AND operation and generate the in-phase activation signal IP-E.

The in-phase activation signal generation circuit 151A may generate the in-phase activation signal IP-E that is activated when the rank on which the read operation indicated by the latch identification signal RSID-L is performed corresponds to the rank including the core die indicated by the core identification signal CID and the latch channel signal RPC-L corresponding to the pseudo channel (e.g., PC0 or PC1) on which the read operation is performed is activated.

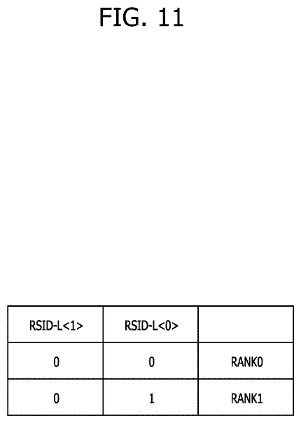

FIG. 11 illustrates an example of the read identification signal RSID that can indicate the rank on which the read operation is performed.

As illustrated in FIG. 11, when the second and first bits RSID-L<1:0> of the latch identification signal RSID-L are generated as a binary bit set of ‘00’ in the read operation, it may be indicated that the read operation is performed on the first rank RANK0. In addition, when the second and first bits RSID-L<1:0> of the latch identification signal RSID-L are generated as a binary bit set of ‘01’ in the read operation, it may be indicated that the read operation is performed on the second rank RANK1.

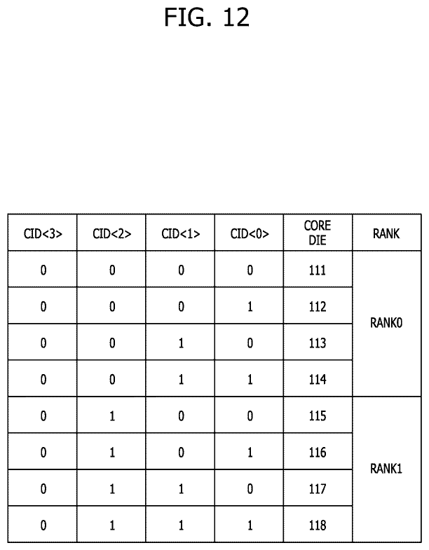

FIG. 12 illustrates an example of the core identification signal CID that can indicate the core die and rank on which the read operation is performed.

As illustrated in FIG. 12, when the fourth to first bits CID<3:0> of the core identification signal CID are generated as a binary bit set of ‘0000’, it may be indicated that the read operation is performed in the first core die 111 of the first rank RANK0, when the fourth to first bits CID<3:0> of the CORE identification signal CID are generated as a binary bit set of ‘0001’, it may be indicated that the read operation is performed in the second core die 112 of the first rank RANK0, when the fourth to first bits CID<3:0> of the CORE identification signal CID are generated as a binary bit set of ‘0010’, it may be indicated that the read operation is performed in the third core die 113 of the first rank RANK0, when the fourth to first bits CID<3:0> of the CORE identification signal CID are generated as a binary bit set of ‘0011’, it may be indicated that the read operation is performed in the fourth core die 114 of the first rank RANK0, when the fourth to first bits CID<3:0> of the CORE identification signal CID are generated as a binary bit set of ‘0100’, it may be indicated that the read operation is performed in the fifth core die 115 of the second rank RANK1, when the fourth to first bits CID<3:0> of the CORE identification signal CID are generated as a binary bit set of ‘0101’, it may be indicated that the read operation is performed in the sixth core die 116 of the second rank RANK1, when the fourth to first bits CID<3:0> of the CORE identification signal CID are generated as a binary bit set of ‘0110’, it may be indicated that the read operation is performed in the seventh core die 117 of the second rank RANK1, and when the fourth to first bits CID<3:0> of the CORE identification signal CID are generated as a binary bit set of ‘0111’, it may be indicated that the read operation is performed in the eighth core die 118 of the second rank RANK1.

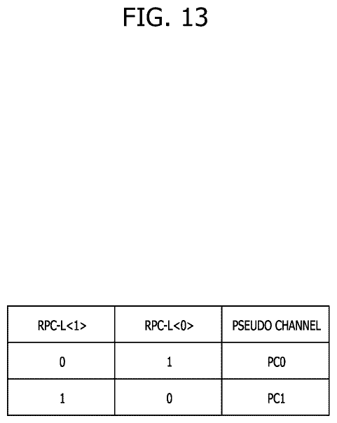

FIG. 13 illustrates an example of the latch channel signal RPC-L that can indicate a pseudo channel (e.g., PC0 or PC1) in which the read operation is performed.

As illustrated in FIG. 13, when the second and first bits RPC-L<1:0> of the latch channel signal RPC-L is set to a binary bit set of ‘01’, it may be indicated that the read operation is performed in the first pseudo channel PC0, and when the second and first bits RPC-L<1:0> of the latch channel signal RPC-L is set to a binary bit set of ‘10’, it may be indicated that the read operation is performed in the second pseudo channel PC1.

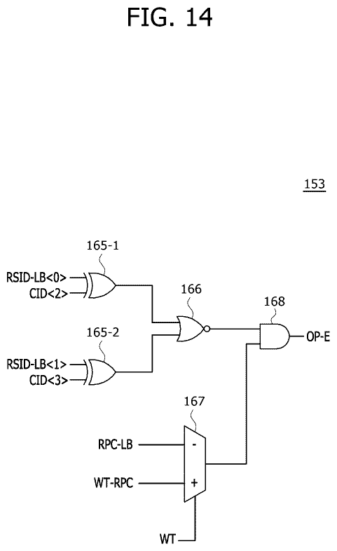

FIG. 14 illustrates a circuit of an embodiment of the out-phase activation signal generation circuit 153 illustrated in FIG. 9. As illustrated in FIG. 14, the out-phase activation signal generation circuit 153 may include exclusive OR devices 165-1 and 165-2, a NOR device 166, a selector 167, and an AND device 168.

The exclusive OR device 165-1 may receive a first bit RSID-LB<0> of the inverted latch identification signal RSID-LB and a third bit CID<2> of the core identification signal CID to perform an exclusive OR operation. The exclusive OR device 165-1 may output a signal of a logic “low” level when the first bit RSID-LB<0> of the inverted latch identification signal RSID-LB and the third bit CID<2> of the core identification signal CID are the same as each other, and may output a signal of a logic “high” level when the first bit RSID-LB<0> of the inverted latch identification signal RSID-LB and the third bit CID<2> of the core identification signal CID are different from each other.

The exclusive OR device 165-2 may receive a second bit RSID-LB<1> of the inverted latch identification signal RSID-LB and a fourth bit CID<3> of the core identification signal CID to perform an exclusive OR operation. The exclusive OR device 165-2 may output a signal of a logic “low” level when the second bit RSID-LB<1> of the inverted latch identification signal RSID-LB and the fourth bit CID<3> of the core identification signal CID are the same as each other, and may output a signal of a logic “high” level when the second bit RSID-LB<1> of the inverted latch identification signal RSID-LB and the fourth bit CID<3> of the core identification signal CID are different from each other.

The NOR device 166 may be electrically connected to the exclusive OR device 165-1 and the exclusive OR device 165-2 to receive the output signal of the exclusive OR device 165-1 and the output signal of the exclusive OR device 165-2 and perform a NOR operation. The NOR device 166 may output a signal of a logic “high” level when the second and first bits RSID-LB<1:0> of the inverted latch identification signal RSID-LB and the fourth and third bits CID<3:2> of the core identification signal CID are the same as each other, and may output a signal of a logic “low” level when the second and first bits RSID-LB<1:0> of the inverted latch identification signal RSID-LB and the fourth and third bits CID<3:2> of the core identification signal CID are different from each other. Here, the second and first bits RSID-LB<1:0> of the inverted latch identification signal RSID-LB may indicate information on the rank on which the read operation is performed, but the number and type of the bits may be changed in various ways depending on the embodiment.

The selector 167 may selectively output one of the inverted latch channel signal RPC-LB and the write setting signal WT-RPC, based on the write signal WT. The selector 163 may output the write setting signal WT-RPC when the write operation is performed, and may output the inverted latch channel signal RPC-LB when the read operation is performed.

The AND device 168 may be electrically connected to the NOR device 166 and the selector 167 to receive the output signal of the NOR device 166 and the output signal of the selector 167. The AND device 168 may receive the output signal of the NOR device 166 and the output signal of the selector 167 to perform an AND operation and generate the out-phase activation signal OP-E.

The out-phase activation signal generation circuit 153A may generate the out-phase activation signal OP-E that is activated when the rank on which the read operation indicated by the inverted latch identification signal RSID-LB is performed corresponds to the rank including the core die indicated by the core identification signal CID and the inverted latch channel signal RPC-LB corresponding to the pseudo channel (e.g., PC0 or PC1) on which the read operation is performed is activated.

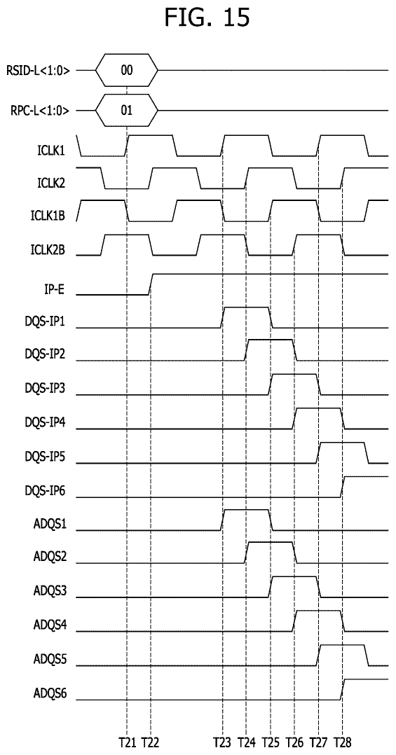

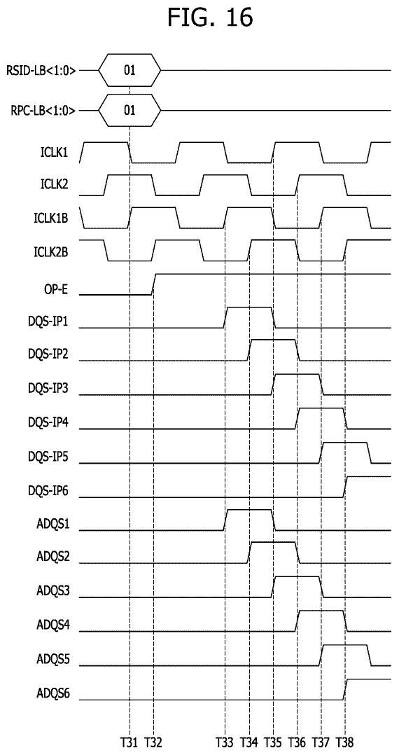

FIGS. 15 and 16 illustrate the operation of an embodiment of the alignment data strobing signal generation circuit 133A illustrated in FIG. 7. The operation of the alignment data strobing signal generation circuit 133A will be described separately when the read operation is performed on the first pseudo channel PC0 of the first rank RANK0 and when the read operation is performed on the first pseudo channel PC0 of the second rank RANK1. Here, assuming that the in-phase data strobing signal DQS-IP includes first to sixth in-phase data strobing signals DQS-IP1˜DQS-IP6 and the alignment data strobing signal ADQS includes first to sixth alignment data strobing signals ADQS1˜ADQS6, the operation may be described as follows.

As illustrated in FIG. 15, at the time point of T21, when the second and first bits RSID-L<1:0> of the latch identification signal RSID-L, set to a binary bit set of ‘00’ are received and the second and first bits RPC-L<1:0> of the latch channel signal RPC-L, set to a binary bit set of ‘01’ are received in synchronization with the in-phase of the internal clock signal ICLK, that is, the first internal clock signal ICLK1, and the read operation on the first pseudo channel PC0 of the first rank RANK0 is performed, the in-phase activation signal generation circuit 151 may generate an activated in-phase activation signal IP-E at the time point of T22. From the time point of T23, when one cycle period of the first internal clock signal ICLK1 has elapsed from the time point of T21, the first to sixth in-phase data strobing signals DQS-IP1˜DQS-IP6 and the first to sixth alignment data strobing signals ADQS1˜ADQS6 may be generated from the first internal clock signal ICLK1, the second internal clock signal ICLK2, the first inverted internal clock signal ICLK1B, and the second inverted internal clock signal ICLK2B. For example, at the time point of T23, the in-phase data strobing signal generation circuit 155 may generate the first in-phase data strobing signal DQS-IP1 according to the first internal clock signal ICLK1, and the data strobing signal summation circuit 159 may generate the first alignment data strobing signal ADQS1 according to the first in-phase data strobing signal DQS-IP1. In addition, at the time point of T24, the in-phase data strobing signal generation circuit 155 may generate the second in-phase data strobing signal DQS-IP2 according to the second internal clock signal ICLK2, and the data strobing signal summation circuit 159 may generate the second alignment data strobing signal ADQS2 according to the second in-phase data strobing signal DQS-IP2. In addition, at the time point of T25, the in-phase data strobing signal generation circuit 155 may generate the third in-phase data strobing signal DQS-IP3 according to the first inverted internal clock signal ICLK1B, and the data strobing signal summation circuit 159 may generate the third alignment data strobing signal ADQS3 according to the third in-phase data strobing signal DQS-IP3. In addition, at the time point of T26, the in-phase data strobing signal generation circuit 155 may generate the fourth in-phase data strobing signal DQS-IP4 according to the second inverted internal clock signal ICLK2B, and the data strobing signal summation circuit 159 may generate the fourth alignment data strobing signal ADQS4 according to the fourth in-phase data strobing signal DQS-IP4. In addition, at the time point of T27, the in-phase data strobing signal generation circuit 155 may generate the fifth in-phase data strobing signal DQS-IP5 according to the first internal clock signal ICLK1, and the data strobing signal summation circuit 159 may generate the fifth alignment data strobing signal ADQS5 according to the fifth in-phase data strobing signal DQS-IP5. In addition, at the time point of T28, the in-phase data strobing signal generation circuit 155 may generate the sixth in-phase data strobing signal DQS-IP6 according to the second internal clock signal ICLK2, and the data strobing signal summation circuit 159 may generate the sixth alignment data strobing signal ADQS6 according to the sixth in-phase data strobing signal DQS-IP6.

As illustrated in FIG. 16, at the time point of T31, when the second and first bits RSID-L<1:0> of the latch identification signal RSID-L, set to a binary bit set of ‘01’ are received and the second and first bits RPC-L<1:0> of the latch channel signal RPC-L, set to a binary bit set of ‘01’ are received in synchronization with the out-phase of the internal clock signal ICLK, that is, the first inverted internal clock signal ICLK1B and the read operation on the first pseudo channel PC0 of the second rank RANK1 is performed, the out-phase activation signal generation circuit 153 may generate an activated out-phase activation signal OP-E at the time point of T32. From the time point of T33, when one cycle period of the first inverted internal clock signal ICLK1B has elapsed from the time point of T31, the first to sixth out-phase data strobing signals DQS-OP1˜DQS-OP6 and the first to sixth alignment data strobing signals ADQS1˜ADQS6 may be generated from the first inverted internal clock signal ICLK1B, the second inverted internal clock signal ICLK2B, the first internal clock signal ICLK1, and the second internal clock signal ICLK2. For example, at the time point of T33, the out-phase data strobing signal generation circuit 157 may generate the first out-phase data strobing signal DQS-OP1 according to the first inverted internal clock signal ICLK1B, and the data strobing signal summation circuit 159 may generate the first alignment data strobing signal ADQS1 according to the first out-phase data strobing signal DQS-OP1. In addition, at the time point of T34, the out-phase data strobing signal generation circuit 157 may generate the second out-phase data strobing signal DQS-OP2 according to the second inverted internal clock signal ICLK2B, and the data strobing signal summation circuit 159 may generate the second alignment data strobing signal ADQS2 according to the second out-phase data strobing signal DQS-OP2. In addition, at the time point of T35, the out-phase data strobing signal generation circuit 157 may generate the third out-phase data strobing signal DQS-OP3 according to the first internal clock signal ICLK1, and the data strobing signal summation circuit 159 may generate the third alignment data strobing signal ADQS3 according to the third out-phase data strobing signal DQS-OP3. In addition, at the time point of T36, the out-phase data strobing signal generation circuit 157 may generate the fourth out-phase data strobing signal DQS-OP4 according to the second internal clock signal ICLK2, and the data strobing signal summation circuit 159 may generate the fourth alignment data strobing signal ADQS4 according to the fourth out-phase data strobing signal DQS-OP4. In addition, at the time point of T37, the out-phase data strobing signal generation circuit 157 may generate the fifth out-phase data strobing signal DQS-OP5 according to the first inverted internal clock signal ICLK1B, and the data strobing signal summation circuit 159 may generate the fifth alignment data strobing signal ADQS5 according to the fifth out-phase data strobing signal DQS-OP5. In addition, at the time point of T38, the out-phase data strobing signal generation circuit 157 may generate the sixth out-phase data strobing signal DQS-OP6 according to the second inverted internal clock signal ICLK2B, and the data strobing signal summation circuit 159 may generate the sixth alignment data strobing signal ADQS6 according to the sixth out-phase data strobing signal DQS-OP6.

FIG. 17 illustrates a configuration of a peripheral region 125B according to another example of the peripheral region 125 illustrated in FIG. 5. As illustrated in FIG. 17, the peripheral region 125B may include control through via arrays (CTR TSV ARRAY (1)˜CTR TSV ARRAY (2)) 171-1˜171-2, data strobing through via arrays (DQS TSV ARRAY (1)˜DQS TSV ARRAY (2)) 172-1˜172-2, an alignment data strobing signal generation circuit (ADQS GEN) 173, a first read data strobing signal transmission circuit (RDQS TX (1)) 175-1, and a second read data strobing signal transmission circuit (RDQS TX (2)) 175-2.

Each of the control through via arrays 171-1 and 171-2 may transmit the read identification signal RSID, the read channel signal RPC, and the internal clock signal ICLK generated in the base die (100 in FIG. 1) to each of the plurality of core dies 111, 112, 113, 114, 115, 116, 117, and 118, passing through the base die 100 and the plurality of core dies 111, 112, 113, 114, 115, 116, 117, and 118. The control through via array 171-1 may be located at the top center of the peripheral region 125B, and the control through via array 171-2 may be located at the bottom center of the peripheral region 125B, but this is only an example and the present disclosure is not limited thereto.

Each of the data strobing through via arrays 172-1 and 172-2 may transmit the read data strobing signal RDQS output from each of the plurality of core dies 111, 112, 113, 114, 115, 116, 117, and 118 to the base die 100, passing through the base die 100 and the plurality of core dies 111, 112, 113, 114, 115, 116, 117, and 118. The data strobing through via array 172-1 may be located in the upper left portion of the peripheral region 125A, and the data strobing through via array 172-2 may be located in the upper right portion of the peripheral region 125A, but this is only an example and the present disclosure is not limited thereto.

The alignment data strobing signal generation circuit 173 may be electrically connected to the control through via arrays 171-1 and 171-2 to receive the read identification signal RSID, the read channel signal RPC, and the internal clock signal ICLK from the control through via arrays 171-1 and 171-2. The alignment data strobing signal generation circuit 173 may generate the alignment data strobing signal ADQS, based on the read identification signal RSID, the read channel signal RPC, and the internal clock signal ICLK. The alignment data strobing signal generation circuit 173 may latch the read identification signal RSID and the read channel signal RPC in synchronization with the internal clock signal ICLK, and may generate the alignment data strobing signal ADQS to transmit the read data strobing signal RDQS to the base die 100 when the read operation is performed on the specific pseudo channel (e.g., PC0 or PC1) of the specific rank (e.g., RANK0 or RANK1), based on the latched read identification signal RSID and read channel signal RPC.

The first read data strobing signal transmission circuit 175-1 may be electrically connected to the alignment data strobing signal generation circuit 173 to receive the alignment data strobing signal ADQS from the alignment data strobing signal generation circuit 173. The first read data strobing signal transmission circuit 175-1 may output the read data strobing signal RDQS generated based on the alignment data strobing signal ADQS to the base die 100 through the data strobing through via array 172-1. For example, the first read data strobing signal transmission circuit 175-1 may generate the read data strobing signal RDQS according to the alignment data strobing signal ADQS, and output the read data strobing signal RDQS to the base die 100 through the data strobing through via array 172-1 when the read operation on the first pseudo channel PC0 of the corresponding rank (e.g., RANK0 or RANK1) is performed. In an embodiment, as the read data strobing signal RDQS is generated according to the alignment data strobing signal ADQS during the transmission period, the first read data strobing signal transmission circuit 175-1 can prevent or mitigate the read data strobing signals RDQS generated for each read operation from overlapping with each other when the read operation on the first pseudo channel PC0 is performed and then the read operation on other pseudo channels (e.g., PC0 or PC1) is performed. The transmission period may be set to one cycle period of the internal clock signal ICLK, but this is only an example and the present disclosure is not limited thereto.

The second read data strobing signal transmission circuit 175-2 may be electrically connected to the alignment data strobing signal generation circuit 173 to receive the alignment data strobing signal ADQS from the alignment data strobing signal generation circuit 173. The second read data strobing signal transmission circuit 175-2 may output the read data strobing signal RDQS generated based on the alignment data strobing signal ADQS to the base die 100 through the data strobing through via array 172-2. For example, the second read data strobing signal transmission circuit 175-2 may generate the read data strobing signal RDQS according to the alignment data strobing signal ADQS and output the read data strobing signal RDQS to the base die 100 through the data strobing through via array 172-2 when the read operation on the second pseudo channel PC1 of the corresponding rank (e.g., RANK0 or RANK1) is performed. In an embodiment, as the read data strobing signal RDQS is generated according to the alignment data strobing signal ADQS during the transmission period, the second read data strobing signal transmission circuit 175-2 can prevent or mitigate the read data strobing signals RDQS generated for each read operation from overlapping with each other when the read operation on the second pseudo channel PC1 is performed and then the read operation on other pseudo channels (e.g., PC0 or PC1) is performed.

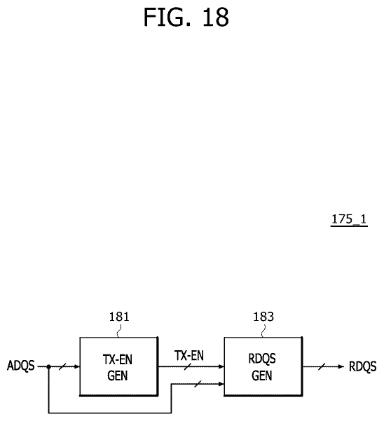

FIG. 18 illustrates a configuration of an example of the first read data strobing signal transmission circuit 175-1 illustrated in FIG. 17. As illustrated in FIG. 18, the first read data strobing signal transmission circuit 175-1 may include a transmission activation signal generation circuit (TX-EN GEN) 181 and a read data strobing signal generation circuit (RDQS GEN) 183.

The transmission activation signal generation circuit 181 may generate a transmission activation signal TX-EN, based on the alignment data strobing signal ADQS. The transmission activation signal generation circuit 181 may combine the bits included in the alignment data strobing signal ADQS to generate bits of the transmission activation signal TX-EN, which are activated during each preset transmission period. As an example, when the alignment data strobing signal ADQS includes first to sixth alignment data strobing signals ADQS1˜ADQS6 and the transmission activation signal TX-EN includes first to fourth transmission activation signals TX-EN1˜TX-EN4, the transmission activation signal generation circuit 181 may generate the first transmission activation signal TX-EN1 that is activated during the transmission period in which the first alignment data strobing signal ADQS1 and the third alignment data strobing signal ADQS3 are generated, may generate the second transmission activation signal TX-EN2 that is activated during the transmission period in which the second alignment data strobing signal ADQS2 and the fourth alignment data strobing signal ADQS4 are generated, may generate the third transmission activation signal TX-EN3 that is activated during the transmission period in which the third alignment data strobing signal ADQS3 and the fifth alignment data strobing signal ADQS5 are generated, and may generate the fourth transmission activation signal TX-EN4 that is activated during the transmission period in which the fourth alignment data strobing signal ADQS4 and the sixth alignment data strobing signal ADQS6 are generated.

The read data strobing signal generation circuit 183 may be electrically connected to the transmission activation signal generation circuit 181 to receive the transmission activation signal TX-EN from the transmission activation signal generation circuit 181. The read data strobing signal generation circuit 183 may generate the read data strobing signal RDQS, based on the transmission activation signal TX-EN and the alignment data strobing signal ADQS. The read data strobing signal generation circuit 183 may generate the read data strobing signal RDQS according to the alignment data strobing signal ADQS during the transmission period in which the transmission activation signal TX-EN is activated. As an example, when the alignment data strobing signal ADQS includes the first to sixth alignment data strobing signals ADQS1˜ADQS6, the transmission activation signal TX-EN includes the first to fourth transmission activation signals TX-EN1˜TX-EN4, and the read data strobing signal RDQS includes first to fourth read data strobing signals RDQS1˜RDQS4, the read data strobing signal generation circuit 183 may generate the first alignment data strobing signal ADQS1 as the first read data strobing signal RDQS1 during the transmission period in which the first transmission activation signal TX-EN1 is activated, may generate the second alignment data strobing signal ADQS2 as the second read data strobing signal RDQS2 during the transmission period in which the second transmission activation signal TX-EN2 is activated, may generate the third alignment data strobing signal ADQS3 as the third read data strobing signal RDQS3 during the transmission period in which the third transmission activation signal TX-EN3 is activated, and may generate the fourth alignment data strobing signal ADQS4 as the fourth read data strobing signal RDQS4 during the transmission period in which the fourth transmission activation signal TX-EN4 is activated.

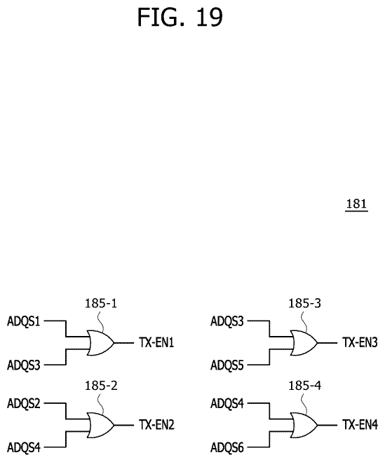

FIG. 19 illustrates a circuit of an example of the transmission activation signal generation circuit 181 illustrated in FIG. 18.

As illustrated in FIG. 19, the transmission activation signal generation circuit 181 may include OR devices 185-1˜185-4. The OR device 185-1 may receive the first alignment data strobing signal ADQS1 and the third alignment data strobing signal ADQS3 to perform an OR operation and generate the first transmission activation signal TX-EN1. The OR device 185-2 may receive the second alignment data strobing signal ADQS2 and the fourth alignment data strobing signal ADQS4 to perform an OR operation and generate the second transmission activation signal TX-EN2. The OR device 185-3 may receive the third alignment data strobing signal ADQS3 and the fifth alignment data strobing signal ADQS5 to perform an OR operation and generate the third transmission activation signal TX-EN3. The OR device 185-4 may receive the fourth alignment data strobing signal ADQS2 and the sixth alignment data strobing signal ADQS6 to perform an OR operation and generate the fourth transmission activation signal TX-EN4.

The transmission activation signal generation circuit 181A may generate the first transmission activation signal TX-EN1 that is activated at a logic “high” level during the transmission period in which each of the first alignment data strobing signal ADQS1 and the third alignment data strobing signal ADQS3 is generated at a logic “high” level. The transmission activation signal generation circuit 181A may generate the second transmission activation signal TX-EN2 that is activated at a logic “high” level during the transmission period in which each of the second alignment data strobing signal ADQS2 and the fourth alignment data strobing signal ADQS4 is generated at a logic “high” level. The transmission activation signal generation circuit 181A may generate the third transmission activation signal TX-EN3 that is activated at a logic “high” level during the transmission period in which each of the third alignment data strobing signal ADQS3 and the fifth alignment data strobing signal ADQS5 is generated at a logic “high” level. The transmission activation signal generation circuit 181A may generate the fourth transmission activation signal TX-EN4 that is activated at a logic “high” level during the transmission period in which each of the fourth alignment data strobing signal ADQS4 and the sixth alignment data strobing signal ADQS6 is generated at a logic “high” level.

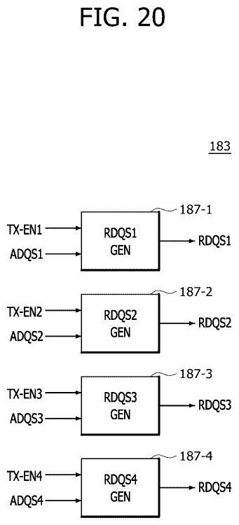

FIG. 20 illustrates a configuration of an embodiment of the read data strobing signal generation circuit 183 illustrated in FIG. 18. As illustrated in FIG. 20, the read data strobing signal generation circuit 183 may include a first read data strobing signal generation circuit (RDQS1 GEN) 187-1, a second read data strobing signal generation circuit (RDQS2 GEN) 187-2, a third read data strobing signal generation circuit (RDQS3 GEN) 187-3, and a fourth read data strobing signal generation circuit (RDQS4 GEN) 187-4.

The first read data strobing signal generation circuit 187-1 may generate the first read data strobing signal RDQS1, based on the first transmission activation signal TX-EN1 and the first alignment data strobing signal ADQS1. For example, the first read data strobing signal generation circuit 187-1 may generate the first alignment data strobing signal ADQS1 as the first read data strobing signal RDQS1 during the transmission period in which the first transmission activation signal TX-EN1 is activated.

The second read data strobing signal generation circuit 187-2 may generate the second read data strobing signal RDQS2, based on the second transmission activation signal TX-EN2 and the second alignment data strobing signal ADQS2. For example, the second read data strobing signal generation circuit 187-2 may generate the second alignment data strobing signal ADQS2 as the second read data strobing signal RDQS2 during the transmission period in which the second transmission activation signal TX-EN2 is activated.

The third read data strobing signal generation circuit 187-3 may generate the third read data strobing signal RDQS3, based on the third transmission activation signal TX-EN3 and the third alignment data strobing signal ADQS3. For example, the third read data strobing signal generation circuit 187-3 may generate the third alignment data strobing signal ADQS3 as the third read data strobing signal RDQS3 during the transmission period in which the third transmission activation signal TX-EN3 is activated.

The fourth read data strobing signal generation circuit 187-4 may generate the fourth read data strobing signal RDQS4, based on the fourth transmission activation signal TX-EN4 and the fourth alignment data strobing signal ADQS4. For example, the fourth read data strobing signal generation circuit 187-4 may generate the fourth alignment data strobing signal ADQS4 as the fourth read data strobing signal RDQS4 during the transmission period in which the fourth transmission activation signal TX-EN4 is activated.

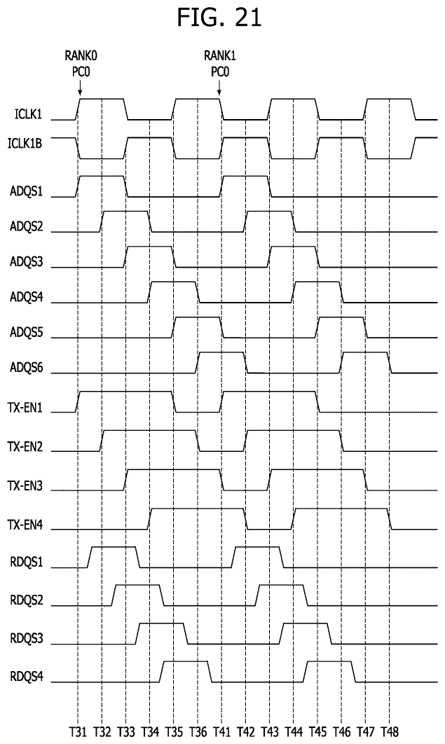

FIG. 21 illustrates an embodiment of the read operation performed in the peripheral region 125B illustrated in FIG. 17. Referring to FIGS. 17 to 21, the read operation may be described separately when the read operation is performed on the first pseudo channel PC0 of the first rank RANK0 and when the read operation is performed on the first pseudo channel PC0 of the second rank RANK1, as follows.

As illustrated in FIGS. 17 and 21, when the read operation is performed on the first pseudo channel PC0 of the first rank RANK0, the alignment data strobing signal generation circuit 173 may generate the first alignment data strobing signal ADQS1 at the time point of T31, may generate the second alignment data strobing signal ADQS2 at the time point of T32, may generate the third alignment data strobing signal ADQS3 at the time point of T33, may generate the fourth alignment data strobing signal ADQS4 at the time point of T34, may generate the fifth alignment data strobing signal ADQS5 at the time point of T35, and may generate the sixth alignment data strobing signal ADQS6 at the time point of T36.

As illustrated in FIGS. 19 and 21, the transmission activation signal generation circuit 181A may generate the first transmission activation signal TX-EN1 that is activated at a logic “high” level during the transmission period T31˜T35 in which the first alignment data strobing signal ADQS1 and the third alignment data strobing signal ADQS3 are generated at a logic “high” level, may generate the second transmission activation signal TX-EN2 that is activated at a logic “high” level during the transmission period T32˜T36 in which the second alignment data strobing signal ADQS2 and the fourth alignment data strobing signal ADQS4 are generated at a logic “high” level, may generate the third transmission activation signal TX-EN3 that is activated at a logic “high” level during the transmission period T33˜T41 in which the third alignment data strobing signal ADQS3 and the fifth alignment data strobing signal ADQS5 are generated at a logic “high” level, and may generate the fourth transmission activation signal TX-EN4 that is activated at a logic “high” level during the transmission period T34˜T42 in which the fourth alignment data strobing signal ADQS4 and the sixth alignment data strobing signal ADQS6 are generated at a logic “high” level.

As illustrated in FIGS. 20 and 21, the first read data strobing signal generation circuit 187-1 may generate the first alignment data strobing signal ADQS1 as the first read data strobing signal RDQS1 during the transmission period T31˜T35 in which the first transmission activation signal TX-EN1 is activated, the second read data strobing signal generation circuit 187-2 may generate the second alignment data strobing signal ADQS2 as the second read data strobing signal RDQS2 during the transmission period T32˜T36 in which the second transmission activation signal TX-EN2 is activated, the third read data strobing signal generation circuit 187-3 may generate the third alignment data strobing signal ADQS3 as the third read data strobing signal RDQS3 during the transmission period T33˜T41 in which the third transmission activation signal TX-EN3 is activated, and the fourth read data strobing signal generation circuit 187-4 may generate the fourth alignment data strobing signal ADQS4 as the fourth read data strobing signal RDQS4 during the transmission period T34˜T42 in which the fourth transmission activation signal TX-EN4 is activated.

As illustrated in FIGS. 17 and 21, when the read operation is performed on the first pseudo channel PC0 of the second rank RANK1, the alignment data strobing signal generation circuit 173 may generate the first alignment data strobing signal ADQS1 at the time point of T41, may generate the second alignment data strobing signal ADQS2 at the time point of T42, may generate the third alignment data strobing signal ADQS3 at the time point of T43, may generate the fourth alignment data strobing signal ADQS4 at the time point of T44, may generate the fifth alignment data strobing signal ADQS5 at the time point of T45, and may generate the sixth alignment data strobing signal ADQS6 at the time point of T46.

As illustrated in FIGS. 19 and 21, the transmission activation signal generation circuit 181A may generate the first transmission activation signal TX-EN1 that is activated at a logic “high” level during the transmission period T41˜T45 in which each of the first alignment data strobing signal ADQS1 and the third alignment data strobing signal ADQS3 is generated at a logic “high” level, may generate the second transmission activation signal TX-EN2 that is activated at a logic “high” level during the transmission period T42˜T46 in which each of the second alignment data strobing signal ADQS2 and the fourth alignment data strobing signal ADQS4 is generated at a logic “high” level, may generate the third transmission activation signal TX-EN3 that is activated at a logic “high” level during the transmission period T43˜T47 in which each of the third alignment data strobing signal ADQS3 and the fifth alignment data strobing signal ADQS5 is generated at a logic “high” level, and may generate the fourth transmission activation signal TX-EN4 that is activated at a logic “high” level during the transmission period T44˜T48 in which each of the fourth alignment data strobing signal ADQS4 and the sixth alignment data strobing signal ADQS6 is generated at a logic “high” level.

As illustrated in FIGS. 20 and 21, the first read data strobing signal generation circuit 187-1 may generate the first alignment data strobing signal ADQS1 as the first read data strobing signal RDQS1 during the transmission period T41˜T45 in which the first transmission activation signal TX-EN1 is activated, the second read data strobing signal generation circuit 187-2 may generate the second alignment data strobing signal ADQS2 as the second read data strobing signal RDQS2 during the transmission period T42˜T46 in which the second transmission activation signal TX-EN2 is activated, the third read data strobing signal generation circuit 187-3 may generate the third alignment data strobing signal ADQS3 as the third read data strobing signal RDQS3 during the transmission period T43˜T47 in which the third transmission activation signal TX-EN3 is activated, and the fourth read data strobing signal generation circuit 187-4 may generate the fourth alignment data strobing signal ADQS4 as the fourth read data strobing signal RDQS4 during the transmission period T44˜T48 in which the fourth transmission activation signal TX-EN4 is activated.

As described above, when the read operation on the first pseudo channel PC0 of the first rank RANK0 and the read operation on the first pseudo channel PC0 of the second rank RANK1 are sequentially performed, the first to fourth read data strobing signals RDQS1˜RDQS4 may be generated with the transmission period secured. Accordingly, in an embodiment, the first to fourth read data strobing signals RDQS1˜RDQS4 generated in the read operation on the first pseudo channel PC0 of the first rank RANK0 and the first to fourth read data strobing signals RDQS1˜RDQS4 generated in the read operation on the first pseudo channel PC0 of the second rank RANK1 can be prevented or mitigated from overlapping with each other.

In the previous description, although the read operation on the first pseudo channel PC0 of the first rank RANK0 and the read operation on the first pseudo channel PC0 of the second rank RANK1 are described as being performed in the same peripheral region 125B, this is only for comparing the two read operations. In an embodiment, it is preferable that the read operation on the first pseudo channel PC0 of the first rank RANK0 and the read operation on the first pseudo channel PC0 of the second rank RANK1 are performed in the peripheral region provided for each. Therefore, in FIG. 21, in an embodiment, it is preferable that the first to sixth alignment data strobing signals ADQS1˜ADQS6, the first to fourth transmission activation signals TX-EN1˜TX-EN4, and the first to fourth read data strobing signals RDQS1˜RDQS4 are also separately generated for each pseudo channel of each rank.

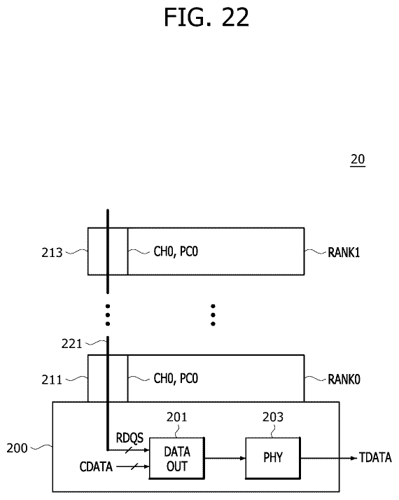

FIG. 22 illustrates a configuration of a stack memory device 20 according to another example of the present disclosure. As illustrated in FIG. 22, the stack memory device 20 may include a base die 200 and a plurality of core dies 211˜ 213.

Each of the plurality of core dies 211˜213 may be stacked over the base die 200. The plurality of core dies 211 and 213 illustrate some of the plurality of core dies stacked over the base die 200. The core die 211 may include a first channel CH0 including a first pseudo channel PC0. The core die 213 may include a first channel CH0 including a first pseudo channel PC0. The first channel CH0 of the core die 211 and the first channel CH0 of the core die 213 may share at least one data path through which data is input and output. The first channel CH0 of the core die 211 may be included in a first rank RANK0, and the first channel CH0 of the core die 213 may be included in a second rank RANK1.

The core die 211 may generate a read data strobing signal RDQS to transmit the read data strobing signal RDQS to the base die 200 through a through via 221 when a read operation on the first pseudo channel PC0 of the first rank RANK0 is performed. The core die 213 may generate the read data strobing signal RDQS to transmit the read data strobing signal RDQS to the base die 200 through a through via 221 when a read operation on the first pseudo channel PC0 of the second rank RANK1 is performed.

The base die 200 may include a data output circuit (DATA OUT) 201 and an interface circuit (PHY) 203. The data output circuit 201 may be electrically connected to the through via 221 to receive the read data strobing signal RDQS from the through via 221. The data output circuit 201 may align core data CDATA, based on the read data strobing signal RDQS to transfer the core data CDATA to the interface circuit 203. For example, the data output circuit 201 may align the core data CDATA output from the core die 211 in synchronization with the read data strobing signal RDQS generated in the core die 211 when the read operation on the first pseudo channel PC0 of the first rank RANK0 is performed. In addition, the data output circuit 201 may align the core data CDATA output from the core die 213 in synchronization with the read data strobing signal RDQS generated in the core die 213 when the read operation on the first pseudo channel PC0 of the second rank RANK1 is performed. The interface circuit 203 may covert the aligned core data CDATA received from the electrically connected data output circuit 201 into transmission data TDATA to transmit the transmission data TDATA to a memory controller (not illustrated).

The stack memory device 20 described above may transmit the read data strobing signal RDQS generated in the core die 211 when the read operation is performed on the first pseudo channel PC0 of the first rank RANK0 and the read data strobing signal RDQS generated in the core die 213 when the read operation is performed on the first pseudo channel PC0 of the second rank RANK1 to the base die 200 through the same through via 221, thereby reducing the number of through vias used to transmit the read data strobing signal RDQS.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A memory device comprising:
an alignment data strobing signal generation circuit configured to receive a read identification signal, read channel signal, and internal clock signal and to generate an alignment data strobing signal from the internal clock signal when a read operation on a specific pseudo channel of a specific rank is performed based on the read identification signal and the read channel signal; and
a core pipe configured to receive the alignment data strobing signal and to output core data output from the specific pseudo channel, based on the alignment data strobing signal.

2. The memory device of claim 1, wherein the read identification signal indicates the specific rank.

3. The memory device of claim 1, wherein the read channel signal indicates the specific pseudo channel.

4. The memory device of claim 1, further comprising a base die configured to receive an external clock signal and an external command and to generate the read identification signal and the read channel signal, based on the external clock signal and the external command.

5. The memory device of claim 4, wherein the base die includes:
a command decoder configured to decode the external command in synchronization with the external clock signal received from a memory controller to generate a read command, a channel signal, and an identification signal; and
a read control circuit configured to generate the read identification signal and the read channel signal, based on the read command, the channel signal, and the identification signal.

6. The memory device of claim 5, wherein the base die further includes an internal clock signal generation circuit configured to divide the external clock signal to generate the internal clock signal.

7. The memory device of claim 4, further comprising a plurality of core dies stacked over the base die,
wherein each of the plurality of core dies includes a plurality of channels, and
wherein each of the plurality of channels includes a plurality of pseudo channels.

8. The memory device of claim 7, wherein the channels included in the core dies form at least one rank for setting a bandwidth.

9. The memory device of claim 7, wherein each of the plurality of core dies includes the alignment data strobing signal generation circuit configured to receive the read identification signal and the read channel signal from the base die to generate the alignment data strobing signal.

10. The memory device of claim 7, wherein each of the plurality of core dies includes the core pipe configured to output the core data to the base die.

11. The memory device of claim 1, wherein the alignment data strobing signal generation circuit includes a latch signal generation circuit configured to generate a latch identification signal, an inverted latch identification signal, a latch channel signal, and an inverted latch channel signal, based on the internal clock signal, the read identification signal, and the read channel signal.

12. The memory device of claim 11, wherein the latch signal generation circuit is configured to:
latch the read identification signal in-phase with the internal clock signal to generate the latch identification signal,
latch the read channel signal in synchronization with the in-phase of the internal clock signal to generate the latch channel signal,
latch the read identification signal out-phase with the internal clock signal to generate the inverted latch identification signal, and
latch the read channel signal in synchronization with the out-phase of the internal clock signal to generate the inverted latch channel signal.

13. The memory device of claim 11, wherein the alignment data strobing signal generation circuit further includes an internal clock signal alignment circuit configured to receive a core identification signal and to generate an alignment data strobing signal, based on the latch identification signal, the inverted latch identification signal, the latch channel signal, the inverted latch channel signal, the internal clock signal, and the core identification signal.

14. The memory device of claim 13, wherein the internal clock signal alignment circuit is configured to generate the alignment data strobing signal, based on the latch identification signal, the latch channel signal, and the core identification signal in-phase with the internal clock signal.

15. The memory device of claim 13, wherein the internal clock signal alignment circuit is configured to generate the alignment data strobing signal from the internal clock signal when the specific rank indicated by the latch identification signal corresponds to a rank including a core die indicated by the core identification signal and the latch channel signal corresponding to the specific pseudo channel is activated.

16. The memory device of claim 15, wherein when the internal clock signal includes a first internal clock signal, a second internal clock signal, a first inverted internal clock signal, and a second inverted internal clock signal, the alignment data strobing signal includes first to sixth alignment data strobing signals, and the latch identification signal and the latch channel signal are generated in synchronization with the first internal clock signal,
the internal clock signal alignment circuit is configured to:
generate the first alignment data strobing signal according to the first internal clock signal,
generate the second alignment data strobing signal according to the second internal clock signal,
generate the third alignment data strobing signal according to the first inverted internal clock signal,
generate the fourth alignment data strobing signal according to) the second inverted internal clock signal,
generate the fifth alignment data strobing signal according to the first internal clock signal, and
generate the sixth alignment data strobing signal according to the second internal clock signal.

17. The memory device of claim 13, wherein the internal clock signal alignment circuit is configured to generate the alignment data strobing signal, based on the inverted latch identification signal, the inverted latch channel signal, and the core identification signal out-phase with the internal clock signal.

18. The memory device of claim 17, wherein the internal clock signal alignment circuit is configured to generate the alignment data strobing signal from the internal clock signal when the specific rank indicated by the inverted latch identification signal corresponds to a rank including a core die indicated by the core identification signal and the inverted latch channel signal corresponding to the specific pseudo channel is activated.

19. The memory device of claim 15, wherein when the internal clock signal includes a first internal clock signal, a second internal clock signal, a first inverted internal clock signal, and a second inverted internal clock signal, the alignment data strobing signal includes first to sixth alignment data strobing signals, and the latch identification signal and the latch channel signal are generated in synchronization with the first inverted internal clock signal,
the internal clock signal alignment circuit is configured to:
generate the first alignment data strobing signal according to the first inverted internal clock signal,
generate the second alignment data strobing signal according to the second inverted internal clock signal,
generate the third alignment data strobing signal according to the first internal clock signal,
generate the fourth alignment data strobing signal according to the second internal clock signal,
generate the fifth alignment data strobing signal according to the first inverted internal clock signal, and
generate the sixth alignment data strobing signal according to the second inverted internal clock signal.

20. The memory device of claim 13, wherein the internal clock signal alignment circuit includes:
an in-phase activation signal generation circuit configured to generate an in-phase activation signal, based on the latch identification signal, the latch channel signal, and the core identification signal;
an out-phase activation signal generation circuit configured to generate an out-phase activation signal, based on the inverted latch identification signal, the inverted latch channel signal, and the core identification signal;
an in-phase data strobing signal generation circuit configured to generate an in-phase data strobing signal from the internal clock signal, based on the in-phase activation signal;
an out-phase data strobing signal generation circuit configured to generate an out-phase data strobing signal from the internal clock signal, based on the out-phase activation signal; and
a data strobing signal summation circuit configured to sum the in-phase data strobing signal and the out-phase data strobing signal to generate the alignment data strobing signal.

21. The memory device of claim 1, further comprising:
a control through via array configured to transmit the read identification signal and the read channel signal received from a base die to the alignment data strobing signal generation circuit; and
a data through via array configured to transmit the core data output from the core pipe to the base die.

22. A memory device comprising:
a plurality of core dies stacked over a base die,
wherein each of the plurality of core dies including an alignment data strobing signal generation circuit are configured to receive an internal clock signal, a read identification signal, and a read channel signal from the base die to generate an alignment data strobing signal, and
wherein the alignment data strobing signal generation circuit is configured to:
generate a latch identification signal and a latch channel signal from the read identification signal and the read channel signal in-phase with the internal clock signal, and generate the alignment data strobing signal, based on the latch identification signal, the latch channel signal, and a core identification signal, and
generate an inverted latch identification signal and an inverted latch channel signal from the read identification signal and the read channel signal out-phase with the internal clock signal, and generate the alignment data strobing signal, based on the inverted latch identification signal, the inverted latch channel signal, and the core identification signal.

23. The memory device of claim 22, wherein the read identification signal indicates a specific rank on which a read operation is performed, and the read channel signal indicates a specific pseudo channel on which the read operation is performed.

24. The memory device of claim 22, wherein when the internal clock signal includes a first internal clock signal, a second internal clock signal, a first inverted internal clock signal, and a second inverted internal clock signal, the alignment data strobing signal includes first to sixth alignment data strobing signals, and the latch identification signal and the latch channel signal are generated in synchronization with the first internal clock signal,
the alignment data strobing signal generation circuit is configured to:
generate a first alignment data strobing signal according to the first internal clock signal,
generate a second alignment data strobing signal according to the second internal clock signal,
generate a third alignment data strobing signal according to the first inverted internal clock signal,
generate a fourth alignment data strobing signal according to the second inverted internal clock signal,
generate a fifth alignment data strobing signal according to the first internal clock signal, and
generate a sixth alignment data strobing signal according to the second internal clock signal.

25. The memory device of claim 22, wherein when the internal clock signal includes a first internal clock signal, a second internal clock signal, a first inverted internal clock signal, and a second inverted internal clock signal, the alignment data strobing signal includes first to sixth alignment data strobing signals, and the latch identification signal and the latch channel signal are generated in synchronization with the first inverted internal clock signal,
the alignment data strobing signal generation circuit is configured to:
generate a first alignment data strobing signal according to the first inverted internal clock signal,
generate a second alignment data strobing signal according to the second inverted internal clock signal,
generate a third alignment data strobing signal according to the first internal clock signal,
generate a fourth alignment data strobing signal according to the second internal clock signal,
generate a fifth alignment data strobing signal according to the first inverted internal clock signal, and
generate a sixth alignment data strobing signal according to the second inverted internal clock signal.

26. The memory device of claim 22, wherein the base die is configured to receive an external clock signal and an external command and to generate the read identification signal and the read channel signal, based on the external clock signal and the external command.

27. The memory device of claim 22, wherein the alignment data strobing signal generation circuit includes:
a latch signal generation circuit configured to generate the latch identification signal, the inverted latch identification signal, the latch channel signal, and the inverted latch channel signal, based on the internal clock signal, the read identification signal, and the read channel signal; and
an internal clock signal alignment circuit configured to generate the alignment data strobing signal, based on the latch identification signal, the inverted latch identification signal, the latch channel signal, the inverted latch channel signal, the internal clock signal, and the core identification signal.

28. The memory device of claim 22, further comprising a core pipe configured to receive the alignment data strobing signal and output core data output from a pseudo channel on which a read operation is performed, based on the alignment data strobing signal.

29. The memory device of claim 28, further comprising:
a control through via array configured to transmit the read identification signal and the read channel signal received from a base die to the alignment data strobing signal generation circuit; and
a data through via array configured to transmit the core data output from the core pipe to the base die.

30. A memory device comprising:
a plurality of core dies stacked over a base die,
wherein each of the plurality of core dies comprises:
an alignment data strobing signal generation circuit configured to receive an internal clock signal, a read identification signal, and a read channel signal from the base die to generate an alignment data strobing signal; and
a read data strobing signal transmission circuit configured to generate a read data strobing signal, based on the alignment data strobing signal, and transmit the read data strobing signal to the base die, and
wherein the read data strobing signals generated from the core dies forming the same rank among the plurality of core dies are transmitted to the base die through the same through via arrays.

31. The memory device of claim 30, wherein the read data strobing signal transmission circuit includes:
a transmission activation signal generation circuit configured to generate a transmission activation signal activated during a transmission period, based on the alignment data strobing signal; and
a read data strobing signal generation circuit configured to generate the read data strobing signal according to the alignment data strobing signal during the transmission period in which the transmission activation signal is activated.

32. The memory device of claim 30, wherein when the alignment data strobing signal includes first to sixth alignment data strobing signals, the transmission activation signal includes first to fourth transmission activation signals, and the read data strobing signal includes first to fourth read data strobing signals,
the transmission activation signal generation circuit is configured to:
generate the first transmission activation signal activated during a first transmission period in which the first alignment data strobing signal and the third alignment data strobing signal are generated,
generate the second transmission activation signal activated during a second transmission period in which the second alignment data strobing signal and the fourth alignment data strobing signal are generated,
generate the third transmission activation signal activated during a third transmission period in which the third alignment data strobing signal and the fifth alignment data strobing signal are generated, and
generate the fourth transmission activation signal activated during a fourth transmission period in which the fourth alignment data strobing signal and the sixth alignment data strobing signal are generated.

33. The memory device of claim 32, wherein the read data strobing signal generation circuit is configured to:
output the first alignment data strobing signal as the first read data strobing signal during the first transmission period,
output the second alignment data strobing signal as the second read data strobing signal during the second transmission period,
output the third alignment data strobing signal as the third read data strobing signal during the third transmission period, and
output the fourth alignment data strobing signal as the fourth read data strobing signal during the fourth transmission period.

34. A memory device comprising:
a plurality of core dies stacked over a base die,
wherein each of the plurality of core dies comprise a plurality of channels,
wherein each of the plurality of channels comprise a first pseudo channel and a second pseudo channel, and
wherein the plurality of channels form a first rank and a second rank for setting bandwidth, and
wherein the memory device is configured to:
receive an internal clock signal. read identification signal, and a read channel signal to generate a first alignment data strobing signal from the internal clock signal, based on the read identification signal and the read channel signal, and generate a first read data strobing signal from the first alignment data strobing signal during a first transmission period, based on the first alignment data strobing signal, when a read operation on the first pseudo channel of the first rank is performed, and
generate a second alignment data strobing signal from the internal clock signal, based on the read identification signal and the read channel signal, and generate a second read data strobing signal from the second alignment data strobing signal during a second transmission period, based on the second alignment data strobing signal, when a read operation on the first pseudo channel of the second rank is performed.

35. A memory device comprising:
a plurality of core dies stacked over a base die,
wherein each of the plurality of core dies comprise a plurality of channels,
wherein each of the plurality of channels comprise a first pseudo channel and a second pseudo channel, and
wherein the plurality of channels form a first rank and a second rank for setting bandwidth, and
wherein the memory device is configured to:
receive an internal clock signal. read identification signal, and a read channel signal to generate a first alignment data strobing signal from the internal clock signal, based on the read identification signal and the read channel signal, and generate a first read data strobing signal from the first alignment data strobing signal during a first transmission period, based on the first alignment data strobing signal, when a read operation on the first pseudo channel of the first rank is performed, and
generate a second alignment data strobing signal from the internal clock signal, based on the read identification signal and the read channel signal, and generate a second read data strobing signal from the second alignment data strobing signal during a second transmission period, based on the second alignment data strobing signal, when a read operation on the second pseudo channel of the second rank is performed.

36. A memory device comprising:
a plurality of core dies stacked over a base die,
wherein each of the plurality of core dies comprise a plurality of channels,
wherein each of the plurality of channels comprise a first pseudo channel and a second pseudo channel,
wherein the plurality of channels form a rank for setting a bandwidth, and
wherein the memory device is configured to:
receive an internal clock signal, read identification signal, and a read channel signal to generate a first alignment data strobing signal from the internal clock signal, based on the read identification signal and the read channel signal, and generate a first read data strobing signal from the first alignment data strobing signal during a first transmission period, based on the first alignment data strobing signal, when a read operation on the first pseudo channel of the rank is performed, and
generate a second alignment data strobing signal from the internal clock signal, based on the read identification signal and the read channel signal, and generate a second read data strobing signal from the second alignment data strobing signal during a second transmission period, based on the second alignment data strobing signal, when a read operation on the second pseudo channel of the rank is performed.
